(19) United States
(12) Patent Application Publication
(10) Pub. No.: US 2026/0196272 A1
(43) Pub. Date: Jul. 9, 2026

(54) MEMORY DEVICE, STORAGE DEVICE INCLUDING THE SAME, AND OPERATING METHOD THEREOF

(71) Applicant: SAMSUNG ELECTRONICS CO., LTD., Suwon-si (KR)

(72) Inventors: Seulji SONG, Suwon-si (KR); Jongmin BAEK, Suwon-si (KR); Hunmo YANG, Suwon-si (KR)

(73) Assignee: SAMSUNG ELECTRONICS CO., LTD., Suwon-si (KR)

(21) Appl. No.: 19/289,653

(22) Filed: Aug. 4, 2025

(30) Foreign Application Priority Data
Jan. 8, 2025 (KR) 10-2025-0002835

(51) Int. Cl. G11C 16/10; G11C 16/04; G11C 16/08; G11C 16/30

(52) U.S. Cl. CPC G11C 16/102; G11C 16/0433; G11C 16/08; G11C 16/30

(57) ABSTRACT

A memory device, including: a cell array comprising a plurality of memory cells, wherein each memory cell from among the plurality of memory cells is connected to a corresponding word line from among a plurality of word lines and a corresponding bit line from among of a plurality of bit lines; a driver circuit configured to output a first driving voltage to a first power line; a compensation circuit connected to the first power line; a decoder circuit configured to program a memory cell by selecting a word line and a bit line based on an address, and providing a charge from the first power line, wherein the charge is floated through the selected word line or the selected bit line; and a control circuit configured to control the compensation circuit to adjust an amount of the charge based on the address.

### CROSS-REFERENCE TO RE APPLICATIONS

This application is based on and claims priority under 35 U.S.C. §119 Korean Patent Application No. 10-2025-0002835, filed on January 8, 2025, in the Korean Intellectual Property Office, the disclosure of which is incorporated by reference herein in its entirety.

### BACKGROUND

### 1. Field

The disclosure relates to an electronic device, and more specifically, to a memory device, a storage device including the same and a method of operating the same.

### 2. Description of Related Art

A memory device may include a plurality of memory cells that may store data. Each memory cell may be programmed to have a state corresponding to its data. When the charge provided to the memory cell is lost due to leakage current, data may not be stored properly in memory cells because normal program operation may not be completed.

### SUMMARY

Provided is a memory device with improved reliability, a storage device including the same and a method of operating the same.

In accordance with an aspect of the disclosure, a memory device includes: a cell array comprising a plurality of memory cells, wherein each memory cell from among the plurality of memory cells is connected to a corresponding word line from among a plurality of word lines and a corresponding bit line from among of a plurality of bit lines; a driver circuit configured to output a first driving voltage to a first power line; a compensation circuit connected to the first power line; a decoder circuit configured to program a memory cell by selecting a word line and a bit line based on an address, and providing a charge from the first power line, wherein the charge is floated through the selected word line or the selected bit line; and a control circuit configured to control the compensation circuit to adjust an amount of the charge based on the address.

In accordance with an aspect of the disclosure, a method for operating a memory device including a cell array including a plurality of memory cells, a decoder circuit and a compensation circuit, includes: outputting a first driving voltage to a first power line; using the decoder circuit, selecting a word line from among a plurality of word lines and a bit line from among a plurality of bit lines based on an address; providing a charge to a memory cell from the first power line, wherein the charge is floated through the selected word line or the selected bit line; and programming the memory cell by outputting a second driving voltage to a second power line, wherein the providing of the charge comprises adjusting an amount of the charge using the compensation circuit based on the address.

In accordance with an aspect of the disclosure, a storage device includes: a memory controller configured to communicate with a host using a compute express link (CXL) protocol; and a memory device comprising a decoder circuit, a compensation circuit, and a cell array comprising a plurality of memory cells, wherein the memory device is configured to: output a first driving voltage to a first power line; using the decoder circuit, select a word line from among a plurality of word lines and a bit line from among a plurality of bit lines based on an address; provide a charge to a memory cell from the first power line, wherein the charge is floated through the selected word line or the selected bit line; program the memory cell by outputting a second driving voltage to a second power line; and adjust an amount of the charge using the compensation circuit based on the address.

### BRIEF DESCRIPTION OF DRAWINGS

The above and other aspects, features, and advantages of certain embodiments of the present disclosure will be more apparent from the following description taken in conjunction with the accompanying drawings, in which:

FIG. 1 is a block diagram illustrating a memory device according to an example embodiment;

FIG. 2 is a drawing for explaining a memory device according to an example embodiment;

FIG. 3 is a drawing for explaining a structure of a cell array according to an example embodiment;

FIG. 4 is a drawing for explaining a cross-sectional structure of a cell array according to an example embodiment;

FIG. 5 is a diagram explaining a decoder circuit and a compensation circuit according to an example embodiment;

FIG. 6 is a waveform diagram for explaining a first program operation of a memory device according to an example embodiment;

FIG. 7A to FIG. 7C are drawings for explaining a first program operation step by step according to an example embodiment;

FIG. 8 is a waveform diagram for explaining a second program operation of a memory device according to an example embodiment;

FIG. 9 is a drawing to explain the relationship between a compensation circuit and an address according to an example embodiment;

FIG. 10 is a flowchart illustrating an operation method of a memory device according to an example embodiment;

FIG. 11 is a flowchart for explaining an operation method of a memory device according to an example embodiment;

FIG. 12 is a drawing for explaining a storage device according to an example embodiment; and

FIG. 13 is a drawing to explain characteristics of a memory cell according to an example embodiment.

### DETAILED DESCRIPTION

Hereinafter, example embodiments are described in detail with reference to the accompanying drawings. Like reference numerals refer to like elements throughout, and redundant or duplicative descriptions thereof may be omitted.

As used herein, expressions such as “at least one of,” when preceding a list of elements, modify the entire list of elements and do not modify the individual elements of the list. For example, the expression, "at least one of A, B, and C," should be understood as including only A, only B, only C, both A and B, both A and C, both B and C, or all of A, B, and C.

As is traditional in the field, the embodiments are described, and illustrated in the drawings, in terms of functional blocks, units and/or modules. Those skilled in the art will appreciate that these blocks, units and/or modules are physically implemented by electronic (or optical) circuits such as logic circuits, discrete components, microprocessors, hard-wired circuits, memory elements, wiring connections, and the like, which may be formed using semiconductor-based fabrication techniques or other manufacturing technologies. In the case of the blocks, units and/or modules being implemented by microprocessors or similar, they may be programmed using software (e.g., microcode) to perform various functions discussed herein and may optionally be driven by firmware and/or software. Alternatively, each block, unit and/or module may be implemented by dedicated hardware, or as a combination of dedicated hardware to perform some functions and a processor (e.g., one or more programmed microprocessors and associated circuitry) to perform other functions. Also, each block, unit and/or module of the embodiments may be physically separated into two or more interacting and discrete blocks, units and/or modules without departing from the present scope. Further, the blocks, units and/or modules of the embodiments may be physically combined into more complex blocks, units and/or modules without departing from the present scope.

As used herein, when an action or operation is referred to as occurring “in response to” an event or occurrence, this may mean that action or operation occurs directly or indirectly in response to or based on the event or occurrence.

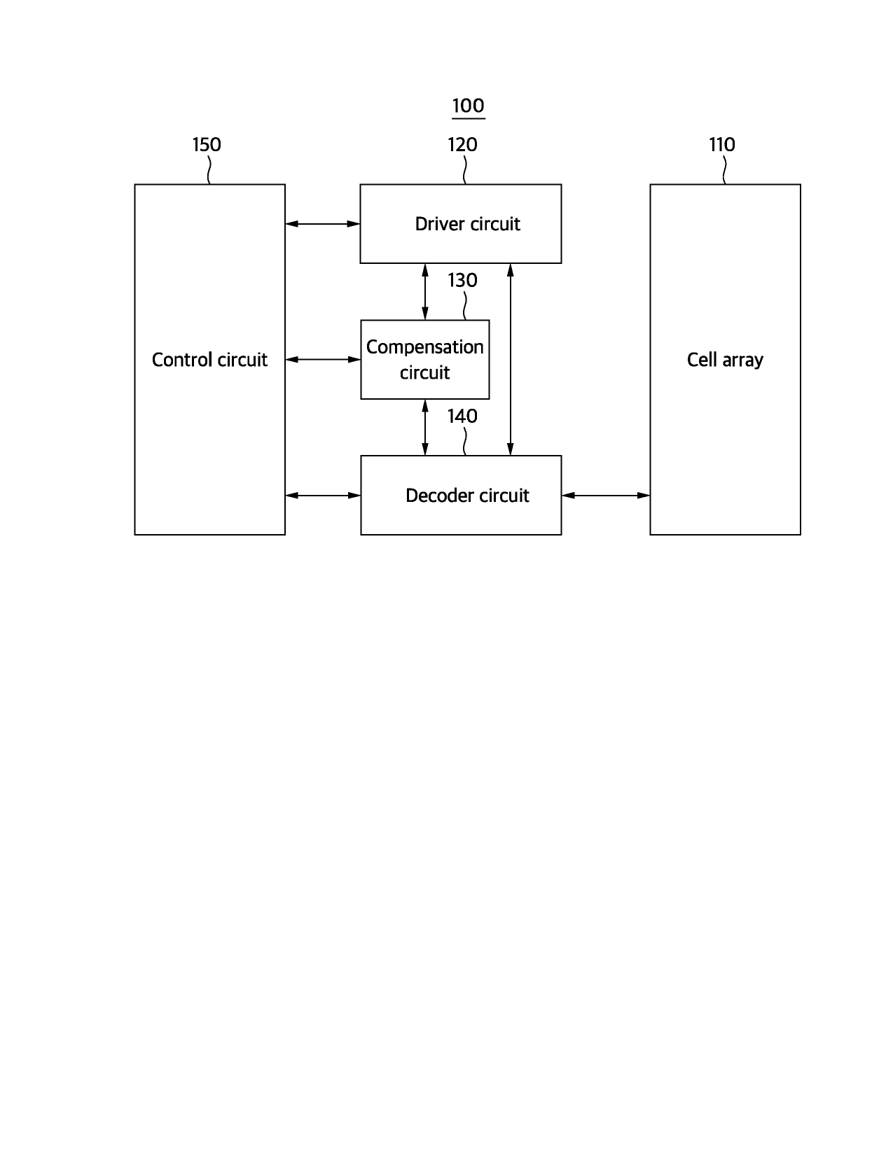

FIG. 1 is a block diagram illustrating a memory device according to an example embodiment.

A memory device 100 may store data or output stored data according to commands provided from outside (e.g., from an outside of the memory device 100). In some example embodiments, the memory device 100 may be implemented as at least one die (or one chip) manufactured by a semiconductor process, and may be included in a standalone package or in a single package with other dies.

Referring to FIG. 1, the memory device 100 may include a cell array 110, a driver circuit 120, a compensation circuit 130, a decoder circuit 140 and a control circuit 150. The cell array 110, the driver circuit 120, the compensation circuit 130, the decoder circuit 140, and the control circuit 150 may be formed on a single semiconductor substrate, or may be formed on two or more semiconductor substrates. In an example embodiment, the memory device 100 may include the cell array 110 and a peripheral circuit or peripheral circuitry. The peripheral circuit may refer to a circuit area other than the cell array 110, and may include the driver circuit 120, the compensation circuit 130, the decoder circuit 140 and the control circuit 150.

The cell array 110 may include a plurality of memory cells. The memory cells may store data. For example, a memory cell may be a selector-only memory (SOM) device or an ovonic threshold switch (OTS)-only memory device. However, this is only an example embodiment, and the memory cell may be implemented using various memory elements such as resistive random access memory (ReRAM), ferroelectric RAM (FeRAM) and phase-change RAM (PRAM). Each of the plurality of memory cells may be connected to one of a plurality of word lines and one of a plurality of bit lines. For example, each memory cell from among the plurality of memory cells may be connected to a corresponding word line from among the plurality of word lines, and a corresponding bit line from among the plurality of bit lines.

The driver circuit 120 may be configured to generate at least one driving voltage for programming the memory cells of the cell array 110. For example, the driver circuit 120 may output each of the first driving voltage and the second driving voltage to the first power line and the second power line. As described below, the compensation circuit 130 and/or the decoder circuit 140 may receive the first driving voltage and/or the second driving voltage using the first power line and/or the second power line.

The compensation circuit 130 may compensate for charge during the operation of programming a memory cell. For example, the compensation circuit 130 may include at least one capacitor circuit connected to the first power line. In an example embodiment, the compensation circuit 130 may further include at least one second capacitor circuit connected to the second power line. The capacitor circuit may include at least one capacitor, and may selectively provide charge (e.g., a charge or charges) by selectively connecting at least one capacitor to the first power line or the second power line.

The decoder circuit 140 may select a word line and a bit line based on an address. For example, the decoder circuit 140 may receive an address or a signal decoded from the address by the control circuit 150, and may select a word line and a bit line based on the address or an address decoded signal. In some example embodiments, the decoder circuit 140 may provide charge through a selected word line or a selected bit line from the floating first power line after being charged with the first driving voltage by the driver circuit 120.

In an example embodiment, a memory cell may be selected based on an address. For example, the memory cell connected to the selected word line and the selected bit line may be selected based on the address. In an example embodiment, the address may include a row address corresponding to the word line and a column address corresponding to the bit line. For example, the word line may be selected according to the row address, and the bit line may be selected according to the column address.

In an example embodiment, the floating first power line may refer to a first power line having a state in which the supply of the first driving voltage is cut off (e.g., turned off, deactivated, or disconnected). For example, when a reference time is elapsed from the time the first driving voltage is output to the first power line, the driver circuit 120 may block the output of the first driving voltage to the first power line, and the first power line may be floated. The reference time may be a preset or predetermined time, or may be a dynamic (or variable) time at which the voltage of the first power line reaches a reference level.

The control circuit 150 may control the overall operation of the memory device 100. For example, the control circuit 150 may control the operation of at least one of the driver circuit 120, the compensation circuit 130 and the decoder circuit 140 based on a command and/or data received from an external device of the memory device 100. The control circuit 150 may generate and output a control signal to control operation. The control circuit 150 may communicate with external devices through any interface. The external devices may be various devices such as memory controller, host device and so on. The control circuit 150 may receive a write command, write data, and an address from an external device. The write data may represent data to be stored according to program operation, and the address may indicate the area (or the region) in which the write data will be stored.

In some example embodiments, the control circuit 150 may control the compensation circuit 130 to adjust the charge provided to the memory cell based on the address. Here, the charge may be supplied to the memory cell through the selected word line or the selected bit line from the floating first power line. As described below, the amount of charge leaked may vary depending on or based on a location of the memory cell in the cell array 110. According to example embodiments, the control circuit 150 may control the compensation circuit 130 to compensate for the charge leaked depending on or based on the area (or the region) including the memory cell based on the address. Accordingly, the data may be safely stored in the memory cell, and the reliability of the memory device 100 may be improved.

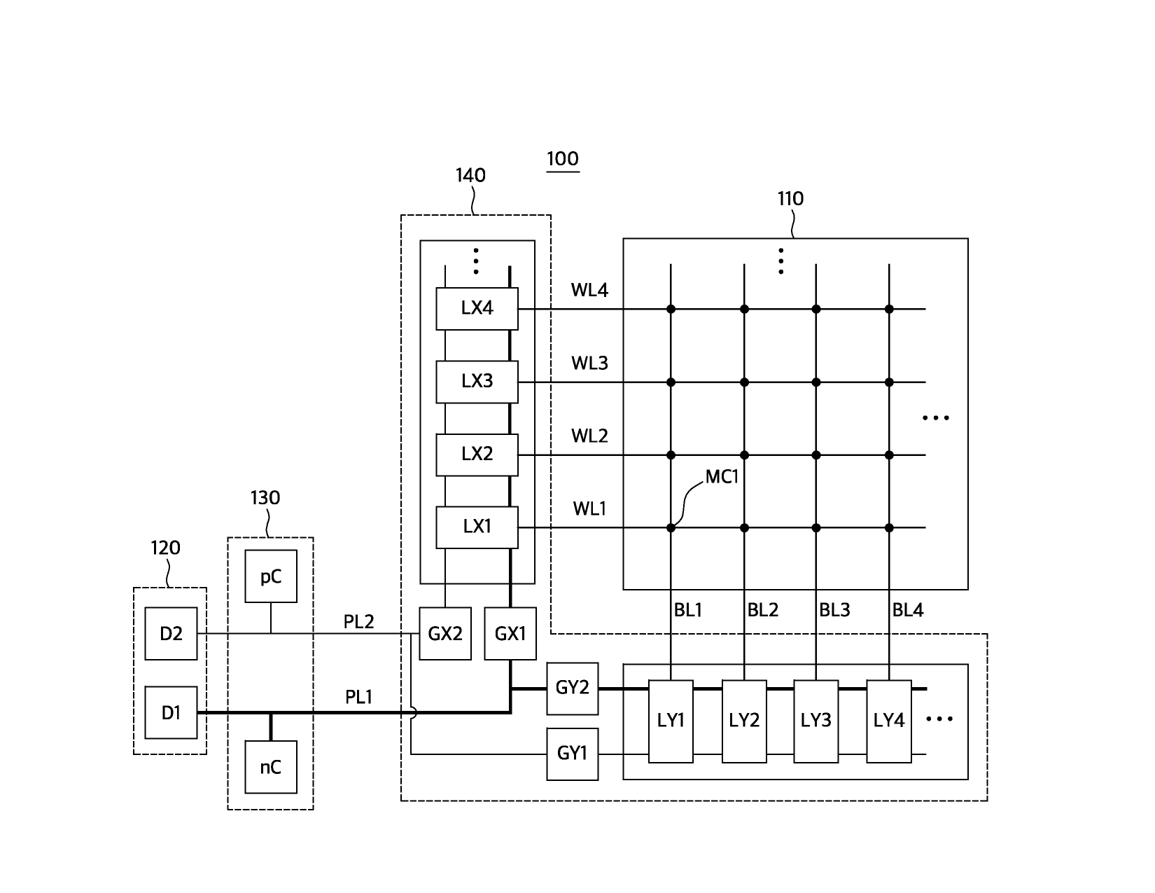

FIG. 2 is a drawing for explaining a memory device according to an example embodiment. In some example embodiments, the memory device 100 of FIG. 2 may be an example of the memory device 100 of FIG. 1.

Referring to FIG. 2, the cell array 110 may include a plurality of memory cells including a first memory cell MC1. In an example embodiment, each memory cell of the plurality of memory cells may be connected to a corresponding word line from among a plurality of word lines (e.g., a first word line WL1, a second word line WL2, a third word line WL3, and a fourth word line WL4) and a corresponding bit line from among a plurality of bit lines (e.g., a first bit line BL1, a second bit line BL2, a third bit line BL3, and a fourth bit line BL4). One memory cell may be connected to one word line and one bit line. In an example embodiment, the memory cell may be placed between a word line and a bit line at the point at which the word line and the bit line intersect. For example, the first memory cell MC1 may be placed between the first word line WL1 and the first bit line BL1 at a point where the first word line WL1 and the first bit line BL1 intersect.

In an example embodiment, the driver circuit 120 may include a first driver circuit D1 connected to a first power line PL1 and a second driver circuit D2 connected to a second power line PL2. The first driver circuit D1 may output (or supply) the first driving voltage to the first power line PL1, or block the output (or supply) of the first driving voltage. The second driver circuit D2 may output (or supply) the second driving voltage to the second power line PL2, or may block the output (or supply). According to embodiments, the control circuit 150 of FIG. 1 may control the first driver circuit D1 to output the first driving voltage through a control signal, or control the second driver circuit D2 to output the second driving voltage.

In an example embodiment, the first driving voltage and the second driving voltage may be voltages having different polarities from each other. For example, the first driving voltage may be the voltage having a first polarity, and the second driving voltage may be a voltage having a second polarity different from the first polarity. For example, one of the first polarity and the second polarity may be negative and the other may be positive. As another example, one of the first polarity and the second polarity may be positive and the other may be negative. Below, example embodiments are described in which the first polarity is negative and the second polarity is positive, but embodiments are not limited thereto.

In an example embodiment, the compensation circuit 130 may include a capacitor circuit nC connected to the first power line PL1 and a capacitor circuit pC connected to the second power line PL2. In some example embodiments, one of the capacitor circuits nC and pC may be omitted. According to embodiments, the number of unit capacitor circuits (included in the capacitor circuits nC and pC) may be implemented in various ways.

In an example embodiment, each of the capacitor circuits nC and pC may include a capacitor and a switch. When the switch of the capacitor circuit nC connected to the first power line PL1 is turned on, the capacitor of the capacitor circuit nC may be connected to the first power line PL1, and when the switch is turned off, the capacitor may be blocked from the first power line PL1. When the switch of the capacitor circuit pC connected to the second power line PL2 is turned on, the capacitor of the capacitor circuit pC may be connected to the second power line PL2, and when the switch is turned off, the capacitor may be blocked from the second power line PL2. According to embodiments, the control circuit 150 may control the switch to turn on or turn off using a control signal. According to embodiments, turning on a switch may refer to activating the switch, for example by switching or maintaining the switch in a state in which the switch is on, active, or connected. According to embodiments, turning off a switch may refer to deactivating the switch, for example by switching or maintaining the switch in a state in which the switch is off, inactive, or disconnected.

In an example embodiment, the decoder circuit 140 may include a plurality of global decoders and a plurality of local decoders. For example, as illustrated in FIG. 2, the decoder circuit 140 may include a first global decoder pair (e.g., a first row global decoder GX1 and a first column global decoder GY1) and a second global decoder pair (e.g., a second row global decoder GX2 and a second column global decoder GY2), and may include a plurality of row local decoders (e.g., a first row local decoder LX1, a second row local decoder LX2, a third row local decoder LX3, and a fourth row local decoder LX4) and a plurality of column local decoders (e.g., a first column local decoder LY1, a column row local decoder LY2, a third column local decoder LY3, and a fourth column local decoder LY4).

The global decoder pair may include one row global decoder and one column global decoder, which are connected to different power lines. The first global decoder pair (e.g., the first row global decoder GX1 and the first column global decoder GY1) may include the first row global decoder GX1 and the first column global decoder GY1. The first row global decoder GX1 may be connected to the first power line PL1, and be connected to multiple row local decoders (e.g., the first row local decoder LX1 to the fourth row local decoder LX4). The first column global decoder GY1 may be connected to the second power line PL2, and may be connected to the first bit line BL1 to the fourth bit line BL4. The second global decoder pair (e.g., the second row global decoder GX2 and the second column global decoder GY2) may include the second row global decoder GX2 and the second column global decoder GY2. The second row global decoder GX2 may be connected to the second power line PL2, and be connected to the first row local decoder LX1 to the fourth row local decoder LX4. The second column global decoder GY2 may be connected to the first power line PL1 and may be connected to the first bit line BL1 to the fourth bit line BL4.

The plurality of local decoders may include the first row local decoder LX1 to the fourth row local decoder LX4 and the first column local decoder LY1 to the fourth column local decoder LY4. Each of the first ow local decoder LX1 to the fourth row local decoder LX4 may be connected to a corresponding word line from among the first word line WL1 to the fourth word line WL4. Each of the first column local decoder LY1 to the fourth column local decoder LY4 may be connected to a corresponding bit line from among the first bit line BL1 to the fourth bit line BL4.

As an example, the control circuit 150 may turn on either the first global decoder pair (e.g., the first row global decoder GX1 and the first column global decoder GY1) or the second global decoder pair (the second row global decoder GX2 and the second column global decoder GY2) depending on or based on the value of the write data. For example, based on the value of the write data being a first value (for example, a value of zero (“0”)), the control circuit 150 may select and turn on the first global decoder pair (e.g., the first row global decoder GX1 and the first column global decoder GY1). As another example, based on the value of the write data being a second value (for example, a value of one (“1”)), the control circuit 150 may select and turn on the second global decoder pair (e.g., the second row global decoder GX2 and the second column global decoder GY2). According to embodiments, the values of the first value and the second value are only an example embodiment and may be implemented differently.

In an example embodiment, the control circuit 150 may select one of the first word line WL1 to the fourth word line WL4 and select one of the first bit line BL1 to the fourth bit line BL4 based on the address. According to embodiments, selecting a word line may indicate selecting a row local decoder that is connected to the word line. Selecting a bit line may indicate selecting a column local decoder that is connected to the bit line.

The control circuit 150 may select and turn on the row local decoder connected to the selected word line. For example, when the first row global decoder GX1 and the first row local decoder LX1 are turned on, the first power line PL1 and the first word line WL1 may be (electrically) connected through the first row global decoder GX1 and the first row local decoder LX1. According to embodiments, when at least one of the first row global decoder GX1 and the first row local decoder LX1 is turned off, the connection between the first power line PL1 and the first word line WL1 may be interrupted.

The control circuit 150 may select and turn on the column local decoder connected to the selected bit line. For example, when the first column global decoder GY1 and the first column local decoder LY1 are turned on, the second power line PL2 and the first bit line BL1 may be (electrically) connected through the first column global decoder GY1 and the first column local decoder LY1. According to embodiments, when at least one of the first column global decoder GY1 and the first column local decoder LY1 is turned off, the connection between the second power line PL2 and the first bit line BL1 may be interrupted.

In an example embodiment, when performing a program operation, the control circuit 150 may control the timing of applying voltage to the selected word line and the selected bit line differently. Accordingly, power consumption may be reduced compared to a case in which voltage is applied to the word line and the bit line simultaneously. For example, the memory device 100 may apply the first voltage to the word line (or the bit line) based on the first driving voltage output to the first power line, and after floating the first power line, apply a second voltage to the bit line (or the word line) based on the second driving voltage output to the second power line. According to embodiments, in this case, charge may be lost due to leakage current depending on or based on the location of the memory cell connected to the first line. For example, based on the current path between the decoder circuit 140 and the memory cell being relatively long, a relatively high leakage current may occur and the charge provided to the memory cell may be reduced. Accordingly, the read window may become narrow because normal program operation may be not completed. The read window may refer to the range of voltages within which data from a memory cell may be accurately read. When increasing the charge uniformly for the memory cell with relatively long current paths, the charge provided to the memory cell having a relatively short current path may be excessive, and unnecessary power consumption may occur. According to example embodiments, by compensating for the charge based on the address of the area (or the region) in which the leakage current becomes severe, low-power-based program operation may be performed normally.

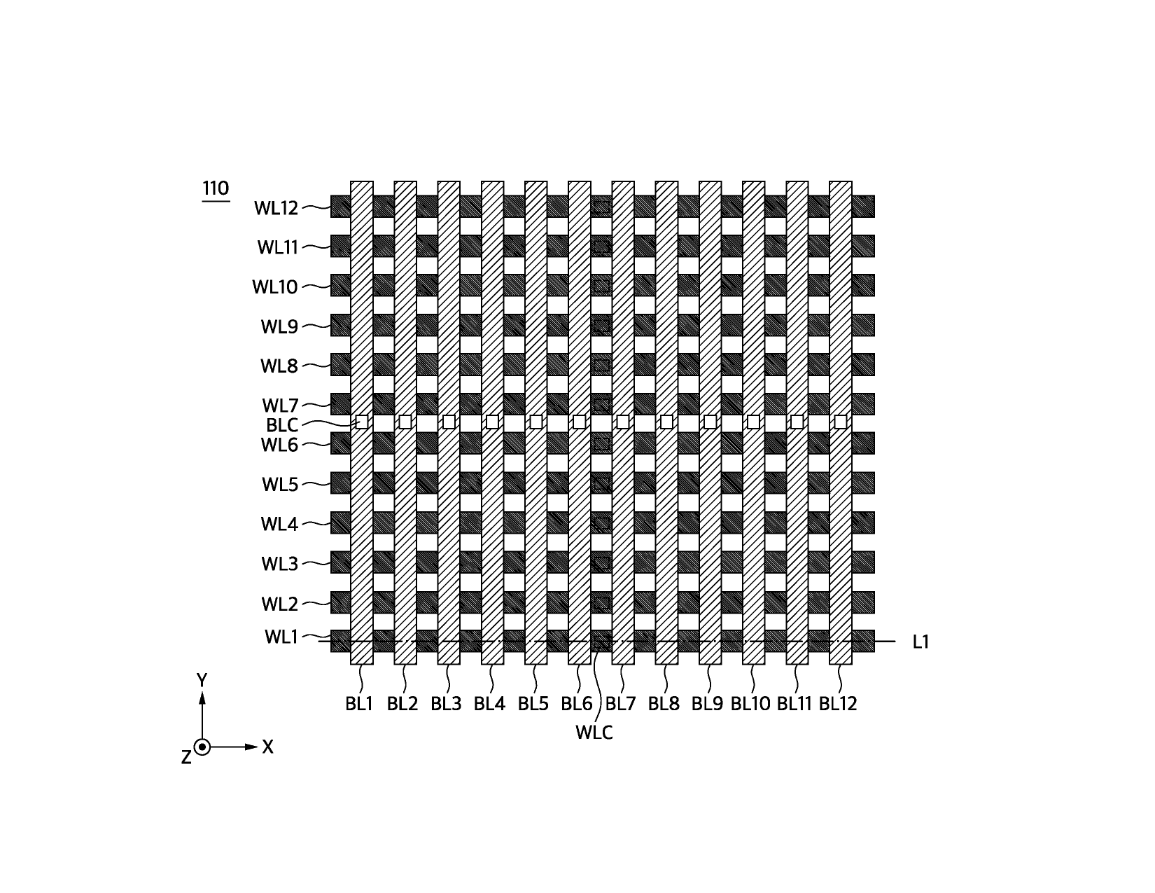

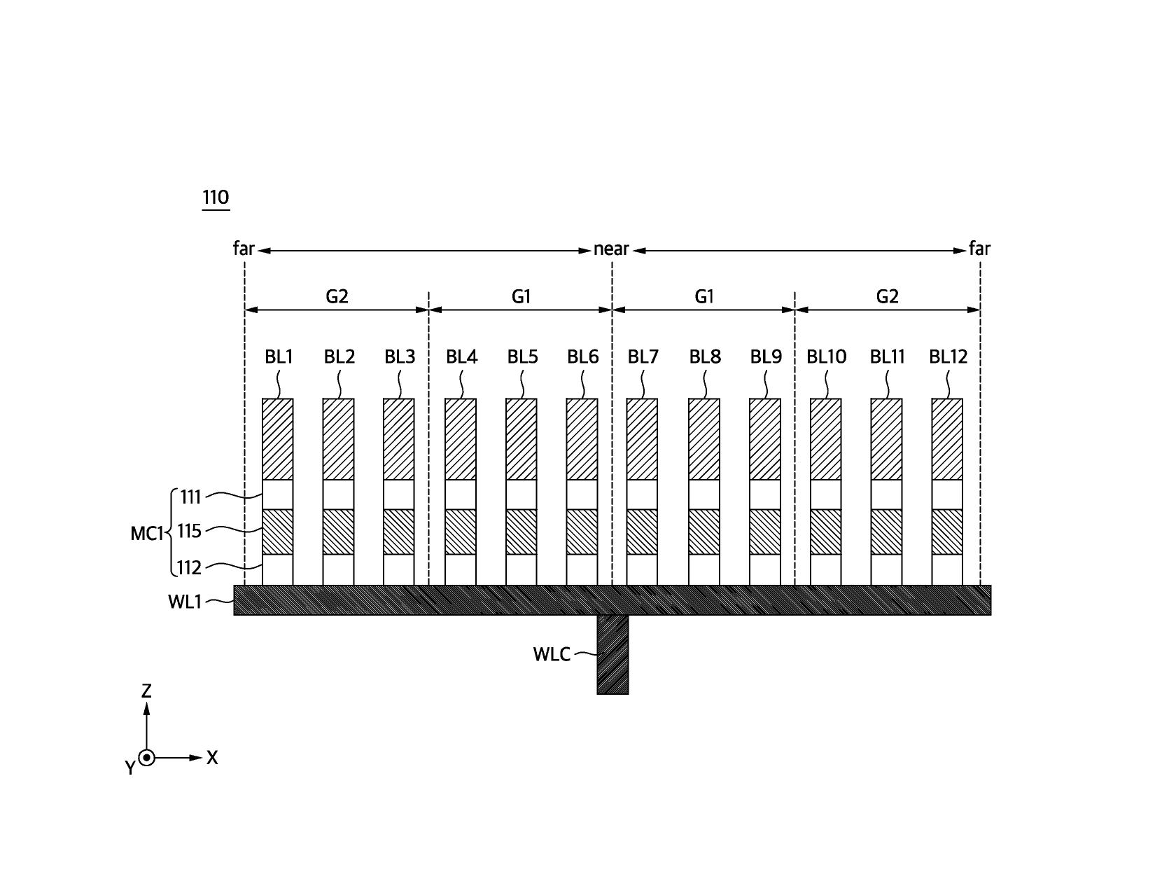

FIG. 3 is a drawing for explaining the structure of a cell array according to an example embodiment. FIG. 4 is a drawing for explaining the cross-sectional structure of a cell array according to an example embodiment. For example, FIG. 4 illustrates a cross-sectional view along a first cross section line L1 of FIG. 3.

Referring to FIG. 3 and FIG. 4, the cell array 110 may include a plurality of memory cells. The cell array 110 may further include the first word line WL1 to the fourth word line WL4 and additional word lines (e.g., a fifth word line WL5, a sixth word line WL6, a seventh word line WL7, an eighth word line WL8, a ninth word line WL9, a tenth word line WL10, an eleventh word line WL11, and a twelfth word line WL12). The cell array 110 may further include the first bit line BL1 to the fourth bit line BL4 and additional bit lines (e.g., a fifth bit line BL5, a sixth bit line BL6, a seventh bit line BL7, an eighth bit line BL8, a ninth bit line BL9, a tenth bit line BL10, an eleventh bit line BL11, and a twelfth bit line BL12. According to embodiments, the number of memory cells, the number of word lines, and the number of bit lines may be implemented in various ways.

In an example embodiment, each of the first word line WL1 to the twelfth word line WL12 may extent along the first direction. The first word line WL1 to the twelfth word line WL12 may be arranged to be spaced apart from each other in the second direction. In an example embodiment, each of the first bit line BL1 to the twelfth bit line BL12 may extend along the second direction. The first bit line BL1 to the twelfth bit line BL12 may be arranged to be spaced apart from each other in the first direction. For example, the first direction may be along the X-axis, and the second direction may be along the Y-axis.

In an example embodiment, the first bit line BL1 to the twelfth bit line BL12 may be arranged in a third direction apart from the first word line WL1 to the twelfth word line WL12. For example, the third direction may be along the Z-axis. For example, the first bit line BL1 to the twelfth bit line BL12 may be positioned above the first word line WL1 to the twelfth word line WL12 in the Z-axis direction. However, this is only an example, and the first bit line BL1 to the twelfth bit line BL12 may be placed lower in the Z-axis direction than the first word line WL1 to the twelfth word line WL12. Below, example embodiments are described in which the first bit line BL1 to the twelfth bit line BL12 are positioned above the first word line WL1 to the twelfth word line WL12 in the Z-axis direction, but embodiments are not limited thereto.

A plurality of memory cells may be formed between the first word line WL1 to the twelfth word line WL12 and the first bit line BL1 to the twelfth bit line BL12. For example, referring to FIG. 4, one memory cell may be formed between each of the first word line WL1 and the first bit line BL1 to the twelfth bit line BL12. Between the first word line WL1 and the first bit line BL1, the first memory cell MC1 may be formed to be connected to the first word line WL1 and the first bit line BL1. Between the first word line WL1 and a second bit line BL2, a second memory cell may be formed that is connected to the first word line WL1 and a second bit line BL2.

The first memory cell MC1 may include a first electrode 111, a second electrode 112 and a selection layer 115. The first electrode 111, the second electrode 112 and the selection layer 115 may be stacked in the third direction. The first electrode 111 may be formed on top of the selection layer 115 and may be connected to the first bit line BL1. The second electrode 112 may be formed below the selection layer 115 and may be connected to the first word line WL1. The first electrode 111 and the second electrode 112 may include a condcutive material. The selection layer 115 may be formed between the first electrode 111 and the second electrode 112. The selection layer 115 may be a single layer that simultaneously performs the functions of storing data and selecting memory cells. In some example embodiments, the selection layer 115 may include a chalcogenide series material. The selection layer 115 may have threshold voltage switching characteristics in which the resistance changes rapidly depending on or based on the voltage applied to each of the first electrode 111 and the second electrode 112. The first memory cell MC1 may have non-volatile memory characteristics that store data even after power is cut off. According to embodiments, the description of the first memory cell MC1 may be equally applied to other memory cells.

A word line contact may be formed in each of the first word line WL1 to the twelfth word line WL12. The word line may be connected to the row local decoder of the decoder circuit 140 through the word line contact. For example, the first word line WL1 may be connected to the row local decoder through a first word line contact WLC. In some example embodiments, the first word line contact WLC may be formed on a surface different from the surface at which the first word line WL1 contacts the memory cell. For example, based on a memory cell being connected to the upper surface of the first word line WL1, the first word line contact WLC may be connected to the lower surface of the first word line WL1. As another example, based on a memory cell being connected to the upper surface of the first word line WL1, the first word line contact WLC may be connected to the lower surface of the first word line WL1. As an example, the first word line contact WLC may be placed in the central portion of the lower surface of the first word line WL1. As another example, the first word line contact WLC may be placed at a location other than the center (for example, edge, a 3/4 point) on the lower surface of the first word line WL1. According to embodiments, the description of the first word line contact WLC may be equally applied to other word line contacts.

Each of the first bit line BL1 to the twelfth bit line BL12 may have a bit line contact formed. The bit line may be connected between column local decoders of the decoder circuit 140 by a bit line contact. For example, the first bit line BL1 may be connected to the column local decoder through a first bit line contact BLC. The first bit line contact BLC may be formed on a surface different from the surface at which the first bit line BL1 contacts the memory cell. For example, based on a memory cell being connected to the lower surface of the first bit line BL1, the first bit line contact BLC may be connected to the upper surface of the first bit line BL1. As another example, based on a memory cell being connected to the lower surface of the first bit line BL1, the first bit line contact BLC may be connected to the upper surface of the first bit line BL1. As an example, the first bit line contact BLC may be placed in the central portion of the upper surface of the first bit line BL1. As another example, the first bit line contact BLC may be placed at a location other than the center (for example, edge, a 3/4 point) on the upper surface of the first bit line BL1. According to embodiments, the description of the first bit line contact BLC may be equally applied to other bit line contacts. According to embodiments, the word line contact and the bit line contact may be briefly referred to as a contact, a first contact, a second contact and so on.

In an example embodiment, the control circuit 150 may identify an area (or the region) including a memory cell in the cell array 110 based on an address. The control circuit 150 may control the compensation circuit 130 based on the identified area. For example, a program operation may be based on the first word line WL1 and the first bit line BL1 being selected, and voltage being first applied (or pre-charged) to the first word line WL1. In this case, the control circuit 150 may identify an area including the first memory cell MC1 (or the first bit line BL1 to which the first memory cell MC1 is connected) among a plurality of memory cells connected to the first word line WL1. The cell array 110 may include a plurality of areas (e.g., at least one first area G1 and at least one second area G2). Each area from among the plurality of areas may include at least one of the plurality of memory cells connected to the first word line WL1. For example, the first memory cell MC1 may be included in a second area G2.

In an example embodiment, the plurality of areas may be distinguished based on the first word line contact WLC formed on the first word line WL1. The plurality of areas may include a first area G1 and the second area G2. The second area G2 may be an area further away than the first area G1 from the contact through which the selected word line or the selected bit line is connected to the decoder circuit 140. For example, a distance between the contact and the second area G2 may be greater than a distance between the contact and the first area G1. For example, a second current path passing through the selected word line or the selected bit line between the second area G2 and the decoder circuit 140 may be longer than the first current path, which passes through the selected word line or the selected bit line between the first area G1 and the decoder circuit 140.

For example, referring to FIG. 4, the first area G1 may be the area closer to the center position at which the first word line contact WLC contacts the first word line WL1, and the second area G2 may be an area further from the center position at which the first word line contact WLC contacts the first word line WL1. Here, the first area G1 may include, or may be referred to as, a near area (illustrated as “near” in FIG. 4), and the second area G2 may include, or may be referred to as, a far area (illustrated as “near” in FIG. 4). The current path between the decoder circuit 140 and the memory cell included in the second area G2 may be longer than the current path between the decoder circuit 140 and the memory cells included in the first area G1. In an example embodiment, the number of areas included in the cell array 110 may vary. In an example embodiment, the number of memory cells included in each of the first area G1 and the second area G2 may be the same or different.

The control circuit 150 may identify an area of a selected memory cell from among a plurality of memory cells connected to the corresponding line through an address of a line that is different from the line (or wiring) connected to the floating power line between the word line and the bit line. For example, based on the first word line WL1 being connected to the floating first power line PL1, the control circuit 150 may identify the area at which the first memory cell MC1 is located among a plurality of memory cells connected to the first word line WL1 through the column address of the selected first bit line BL1.

The control circuit 150 may control the compensation circuit 130 to vary the amount of charge compensation depending on or based on the area including the first memory cell MC1. Here, the amount of charge compensation may indicate the degree to which the charge is compensated (or the amount of charge). For example, based on the first memory cell MC1 being included in the second area G2, the control circuit 150 may compensate for the charge provided to the first memory cell MC1 with a larger compensation amount, and based on the first memory cell MC1 being included in the first area G1, the control circuit 150 may compensate for the charge provided to the first memory cell MC1 with a smaller compensation amount. Compensating the charge with the smaller compensation amount may include cases in which the charge is not compensated.

In an example embodiment, the compensation circuit 130 may include a first capacitor and a first switch. The first switch may be placed between the first capacitor and the first power line PL1. In this case, the control circuit 150 may control the first switch depending on or based on an identified area.

As an example, based on the identified area being the first area G1, the control circuit 150 may turn off the first switch while the first power line PL1 is floating. Accordingly, the charge stored in the first capacitor may not be supplied to the memory cell of the first area G1 through the first power line PL1. As another example, the control circuit 150, based on the identified area being the second area G2, may turn on the first switch while the first power line PL1 is floating. Accordingly, the charge stored in the first capacitor may be supplied to the memory cell of the second area G2 through the first power line PL1. Here, the second area G2 may be an area further away from the contact through which the selected word line (or the selected bit line) is connected to the decoder circuit 140 than the first area G1 is from the contact. The contact may be the first word line contact WLC (or the first bit line contact BLC).

In an example embodiment, the compensation circuit 130 may further include a second capacitor and a second switch. The second switch may be placed between the second capacitor and the first power line PL1. In this case, the control circuit 150 may control the first switch and the second switch based on the identified area.

In an example embodiment, the capacitance of the first capacitor may be different from the capacitance of the second capacitor. Here, the capacitance of the first capacitor may be less than the capacitance of the second capacitor. As an example, based on the identified area being the first area G1, the control circuit 150 may turn on the first switch and turn off the second switch while the first power line PL1 is floating. As another example, based on the identified area is the second area G2, the control circuit 150 may turn off the first switch and turn on the second switch while the first power line PL1 is floating. According to embodiments, here, the first power line PL1 is used as an example, but this may be modified and implemented in a case in which the floating power line is the second power line PL2.

As an example, based on the identified area being the first area G1, the control circuit 150 may turn on one switch from among the first switch and the second switch, and turn off the remaining switch while the first power line PL1 is floating. As another example, based on the identified area being the second area G2, the control circuit 150 may turn on the first switch and the second switch while the first power line PL1 is floating. According to embodiments, here, the first power line PL1 is used as an example, but this may be modified and implemented in a case in which the floating power line is the second power line PL2.

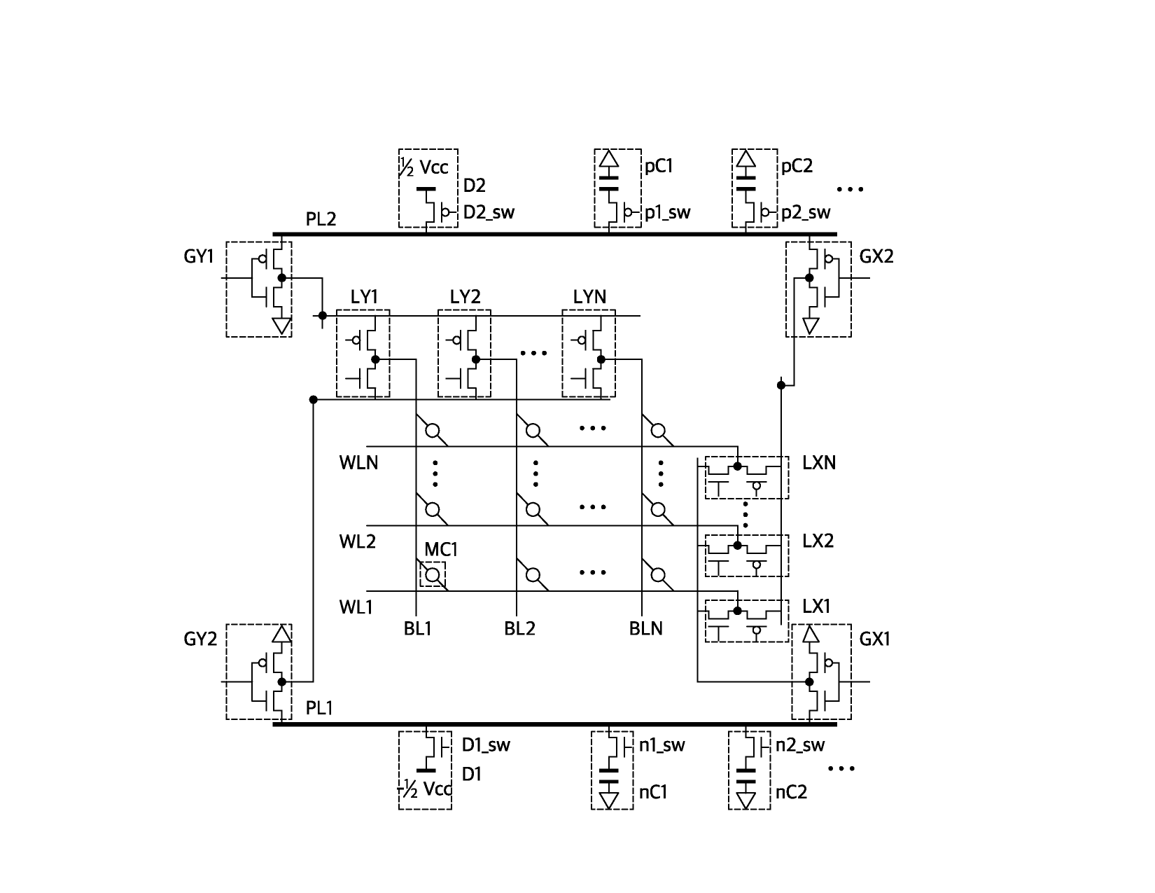

FIG. 5 is a diagram explaining a decoder circuit and a compensation circuit according to an example embodiment.

Referring to FIG. 2 and FIG. 5, the driver circuit 120 may include the first driver circuit D1 connected to the first power line PL1 and the second driver circuit D2 connected to the second power line PL2.

The first driver circuit D1 may include a first driving switch D1_sw. The control circuit 150 may turn on or turn off the first driving switch D1_sw using a control signal. Based on the first driving switch D1_sw being turned on, the first driving voltage (-1/2Vcc) may be output to the first power line PL1. Based on the first driving switch D1_sw being turned off, the output of the first driving voltage (-1/2Vcc) may be blocked. In this case, the first power line PL1 may be floated. The second driver circuit D2 may include a second driving switch D2_sw. The control circuit 150 may turn on or turn off the second driving switch D2_sw depending on or based on the control signal. Based on the second driving switch D2_sw being turned on, the second driving voltage (1/2Vcc) may be output to the second power line PL2, and based on the second driving switch D2_sw being turned off, the output of the second driving voltage (1/2Vcc) may be blocked. In this case, the second power line PL2 may be floated.

In an example embodiment, the first driving voltage (-1/2Vcc) may be a voltage having the first polarity, and the second driving voltage (1/2Vcc) may be a voltage having the second polarity. In this case, the first driving switch D1_sw may include a first type field effect transistor (FET) or metal-oxide-semiconductor (MOS) corresponding to the first polarity of the first driving voltage (-1/2Vcc). The second driving switch D2_sw may include a second type FET or MOS corresponding to the second polarity of the second driving voltage (1/2Vcc). For example, the first polarity may be negative and the second polarity may be positive. In this case, the first type of FET may be an n-channel FET (NFET), and the second type of FET may be a p-channel FET (PFET). The first type of MOS may be an n-channel MOS (NMOS), and the second type of MOS may be a p-channel MOS (PMOS).

In an example embodiment, the compensation circuit 130 may include capacitor circuits (e.g., a capacitor circuit nC1 and a capacitor circuit nC2) connected to the first power line PL1. Each of the capacitor circuits nC1 and nC2 may include a capacitor and switches (e.g., a switch n1_sw and a switch n2_sw). The capacitor may be charged by the first driving voltage (-1/2Vcc) of the first power line PL1. The control circuit 150 may control the switches n1_sw and n2_sw using a control signal to connect or block the capacitor to the first power line PL1. The switches n1_sw and n2_sw of the capacitor circuits nC1 and nC2 may include the MOS of the type corresponding to the first driving voltage (-1/2Vcc). For example, depending on or based on the negative first driving voltage (-1/2Vcc), the switches n1_sw and n2_sw may include the NMOS, and the capacitor may be charged with a negative charge.

In an example embodiment, the compensation circuit 130 may include capacitor circuits (e.g., a capacitor circuit pC1 and a capacitor circuit pC2) connected to the second power line PL2. Each of the capacitor circuits pC1 and pC2 may include a capacitor and a switch (e.g., a switch p1_sw and a switch p2_sw). The capacitor may be charged by the second driving voltage (1/2Vcc) of the second power line PL2. The control circuit 150 may control the switches (e.g., the switch p1_sw and the switch p2_sw) using a control signal to connect or block the capacitor to the second power line PL2. The switches p1_sw and p2_sw of the capacitor circuits pC1 and pC2 may include a second type of MOS corresponding to the second driving voltage (1/2Vcc). For example, depending on or based on the positive second driving voltage (1/2Vcc), the switches (p1_sw and p2_sw may include the PMOS, and the capacitor may be charged with a positive charge.

As an example, the compensation circuit 130 may only include the capacitor circuits nC1 and nC2 connected to the first power line PL1, and a capacitor circuit connected to the second power line PL2 may be omitted. As another example, the compensation circuit 130 may only include the capacitor circuits pC1 and pC2 connected to the second power line PL2, and a capacitor circuit connected to the first power line PL1 may be omitted.

As an example, the memory device 100 may perform the first program operation that may include outputting the first driving voltage (-1/2Vcc) to the first power line PL1, and outputting the second driving voltage (1/2Vcc) to the second power line PL2. Here, after the first driving voltage (-1/2Vcc) is output to the first power line PL1, while the first power line PL1 is floating, the control circuit 150 may selectively turn on the switches n1_sw and n2_sw of the capacitor circuits nC1 and nC2 based on the address.

As another example, the memory device 100 may perform a second program operation that may include outputting the second driving voltage (1/2Vcc) first on the second power line PL2, and outputting the first driving voltage (-1/2Vcc) to the first power line PL1. Here, after the second driving voltage (1/2Vcc) is output to the second power line PL2, while the second power line PL2 is floating, the control circuit 150 may selectively turn on the switches p1_sw and p2_sw of the capacitor circuits pC1 and pC2 based on the address.

A plurality of global decoders may be connected between a plurality of local decoders and the first power line PL1 and the second power line PL2. Each global decoder may connect the local decoder to the power lines or block the local decoder from the power lines. The control circuit 150 may turn on either the first global decoder pair (the first row global decoder GX1 and the first column global decoder GY1) or the second global decoder pair (the second row global decoder GX2 and the second column global decoder GY2) depending on or based on the value of the write data, and turn off the other one that is unselected.

Each of the plurality of global decoders may include a transistor. For example, as illustrated in FIG. 5, the first row global decoder GX1 may include the NMOS and the PMOS. In this case, the gates of each of the NMOS and the PMOS may be connected to each other. The gates of the NMOS and the PMOS may receive the same input signal and operate complementarily. For example, based on the input signal being high, the NMOS may be turned on and the PMOS may be turned off, and based on the input signal being low, the NMOS may be turned off and the PMOS may be turned on. The input signal may be one of the control signals output from the control circuit 150.

The NMOS and the PMOS of the first row global decoder GX1 may be connected to the first row local decoder LX1 to an Nth row local decoder LXN (where N is an integer greater than 1). The NMOS and the PMOS of the second row global decoder GX2 may be connected to the first row local decoder LX1 to the Nth row local decoder LXN. The NMOS and the PMOS of the first column global decoder GY1 may be connected to the first column local decoder LY1 to an Nth column local decoder LYN. The NMOS and the PMOS of the second column global decoder GY2 may be connected to the first column local decoder LY1 to the Nth column local decoder LYN.

The NMOS of each of the first row global decoder GX1 and the second column global decoder GY2 may be connected to the first power line PL1. The PMOS of each of the first row global decoder GX1 and the second column global decoder GY2 may be connected to ground. The PMOS of the first column global decoder GY1 and the second row global decoder GX2 may be connected to the second power line PL2. The NMOS of each of the first column global decoder GY1 and the second row global decoder GX2 may be connected to ground.

A plurality of local decoders may be connected between a plurality of global decoders and a plurality of memory cells. Each of the plurality of local decoders may connect or block the global decoder and memory cells.

The plurality of local decoders may include the first row local decoder LX1 to the Nth row local decoder LXN and the first column local decoder LY1 to the Nth column local decoder LYN. Each of the first row local decoder LX1 to the Nth row local decoder LXN may be connected to a corresponding word line from among a plurality of word lines including the first word line WL1 to an Nth word line WLN. For example, each of the first row local decoder LX1 to the Nth row local decoder LXN may be connected to one of the plurality of memory cells through the corresponding word line. Each of the first column local decoder LY1 to the Nth column local decoder LYN may be connected to a corresponding bit line from among a plurality of bit lines including the first bit line BL1 to an Nth bit line BLN. For example, each of the first column local decoder LY1 to the Nth column local decoder LYN may be connected to one of the plurality of memory cells by a corresponding bit line. The decoder circuit 140 may select one of the first word line WL1 to the Nth word line WLN based on the address, and select either the first bit line BL1 to the Nth bit line BLN. For example, based on the address, the decoder circuit 140 may select one of the first row local decoder LX1 to the Nth row local decoder LXN and select one of the first column local decoder LY1 to the Nth column local decoder LYN. Accordingly, one memory cell may be selected.

Each of the first row local decoder LX1 to the Nth row local decoder LXN may include a transistor. For example, each of the first row local decoder LX1 to the Nth row local decoder LXN may include the NMOS and the PMOS. The NMOS and the PMOS of each of the first row local decoder LX1 to the Nth row local decoder LXN may be connected by a word line contact to one of the first word line WL1 to the Nth word line WLN. The NMOS of each of the first row local decoder LX1 to the Nth row local decoder LXN may be connected to the first row global decoder GX1, and the PMOS of each of the first row local decoder LX1 to the Nth row local decoder LXN may be connected to the second row global decoder GX2.

The gates of the NMOS and the PMOS of each of the first row local decoder LX1 to the Nth row local decoder LXN may be separated or connected. The gate may receive either a turn-on signal or a turn-off signal. A turn-on signal may be input to the gate of the row local decoder selected according to the row address, and a turn-off signal may be input to the gate of another unselected row local decoder. The turn-on signal and the turn-off signal may be generated from the decoder circuit 140 or the control circuit 150.

Each of the first column local decoder LY1 to the Nth column local decoder LYN may include a transistor. For example, each of the first column local decoder LY1 to the Nth column local decoder LYN may include the NMOS and the PMOS. The NMOS and the PMOS of each of the first column local decoder LY1 to the Nth column local decoder LYN may be connected by a bit line contact to one of the first bit line BL1 to the Nth bit line BLN. The PMOS of each of the first column local decoder LY1 to the Nth column local decoder LYN may be connected to the first column global decoder GY1, and the NMOS of each of the first column local decoder LY1 to the Nth column local decoder LYN may be connected to the second column global decoder GY2.

The gates of the NMOS and the PMOS of each of the first column local decoder LY1 to the Nth column local decoder LYN may be separated or connected. The gate may receive either a turn-on signal or a turn-off signal. The turn-on signal may be input to the gate of the column local decoder selected according to the column address, and the turn-off signal may be input to the gate of another unselected column local decoder. The turn-on signal and the turn-off signal may be generated from the decoder circuit 140 or the control circuit 150.

According to embodiments, the number of row local decoders (e.g., the first row local decoder LX1 to the Nth row local decoder LXN), the number of word lines (e.g., the first word line WL1 to the Nth word line WLN), the number of column local decoder (e.g., the first column local decoder LY1 to the Nth column local decoder LYN), the number of bit lines (e.g., the first bit line BL1 to the Nth bit line BLN), and the number of memory cells may be implemented in various variations.

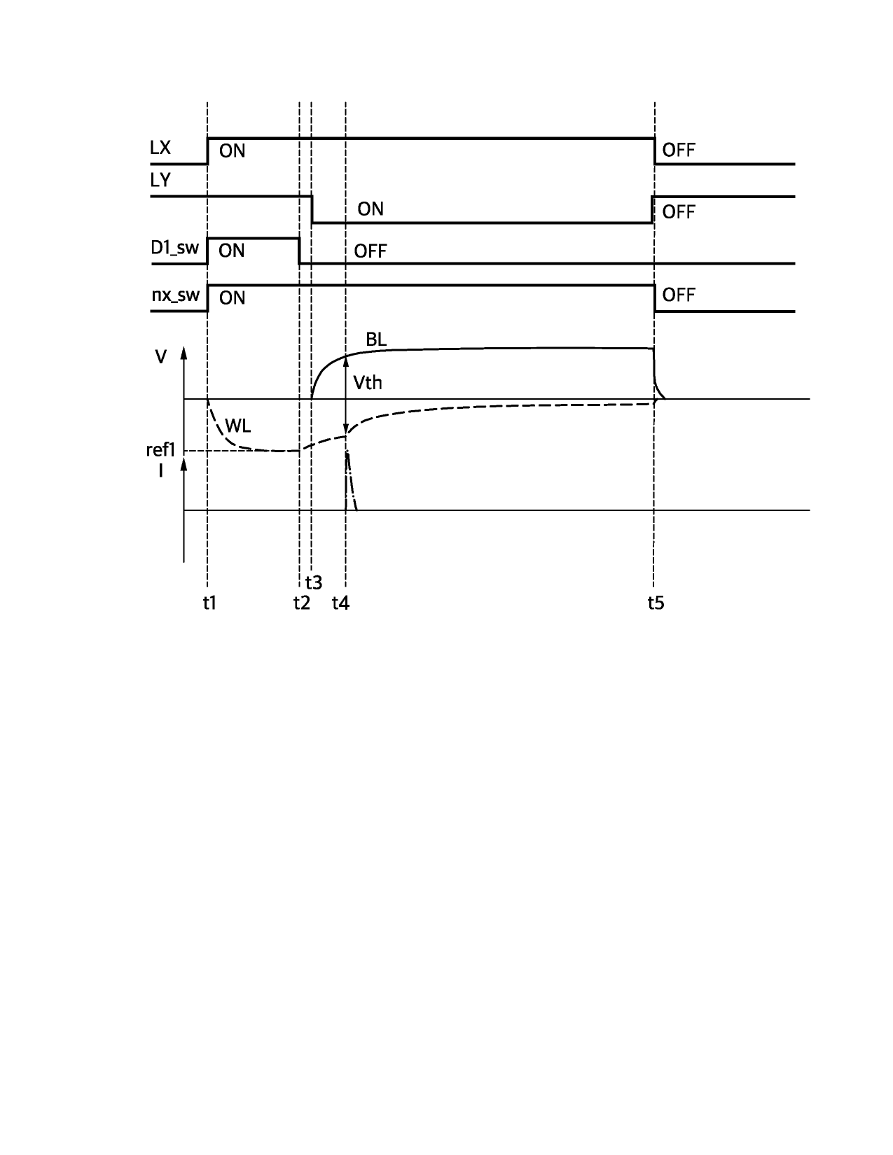

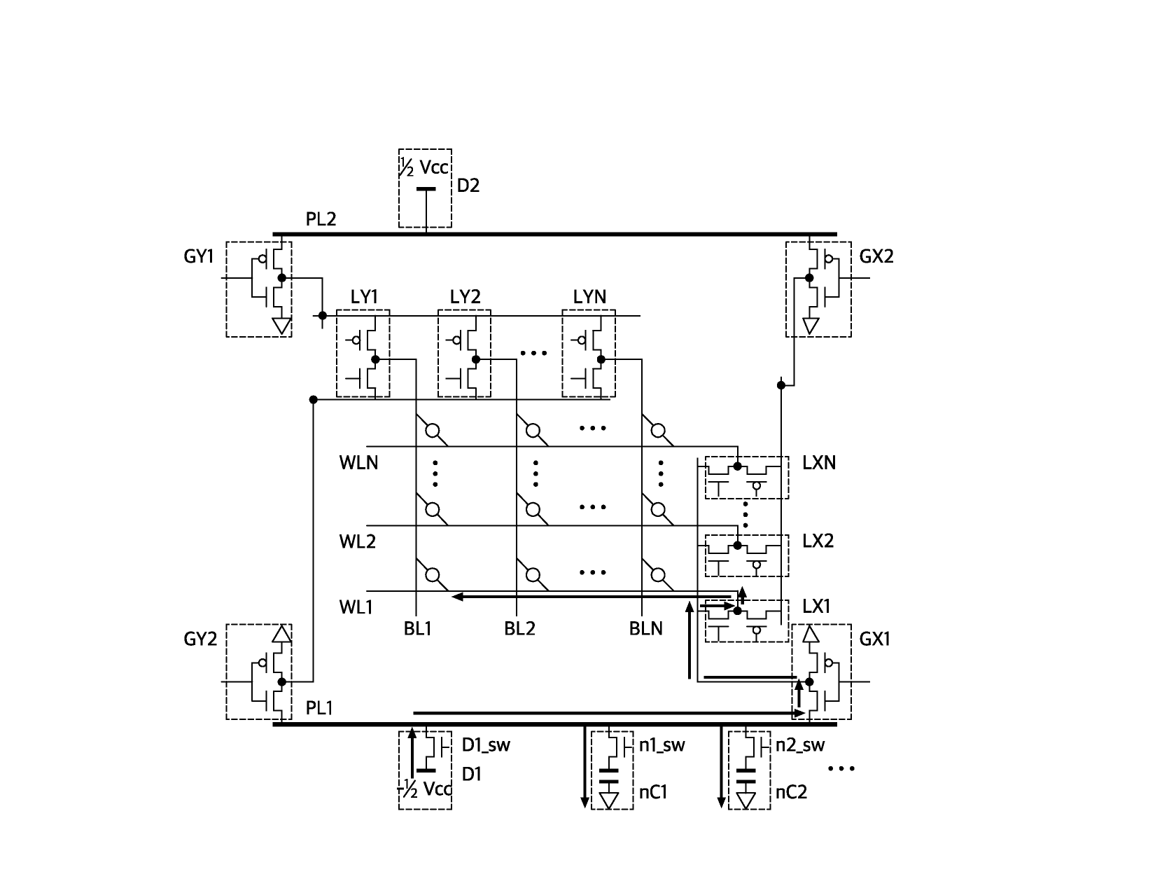

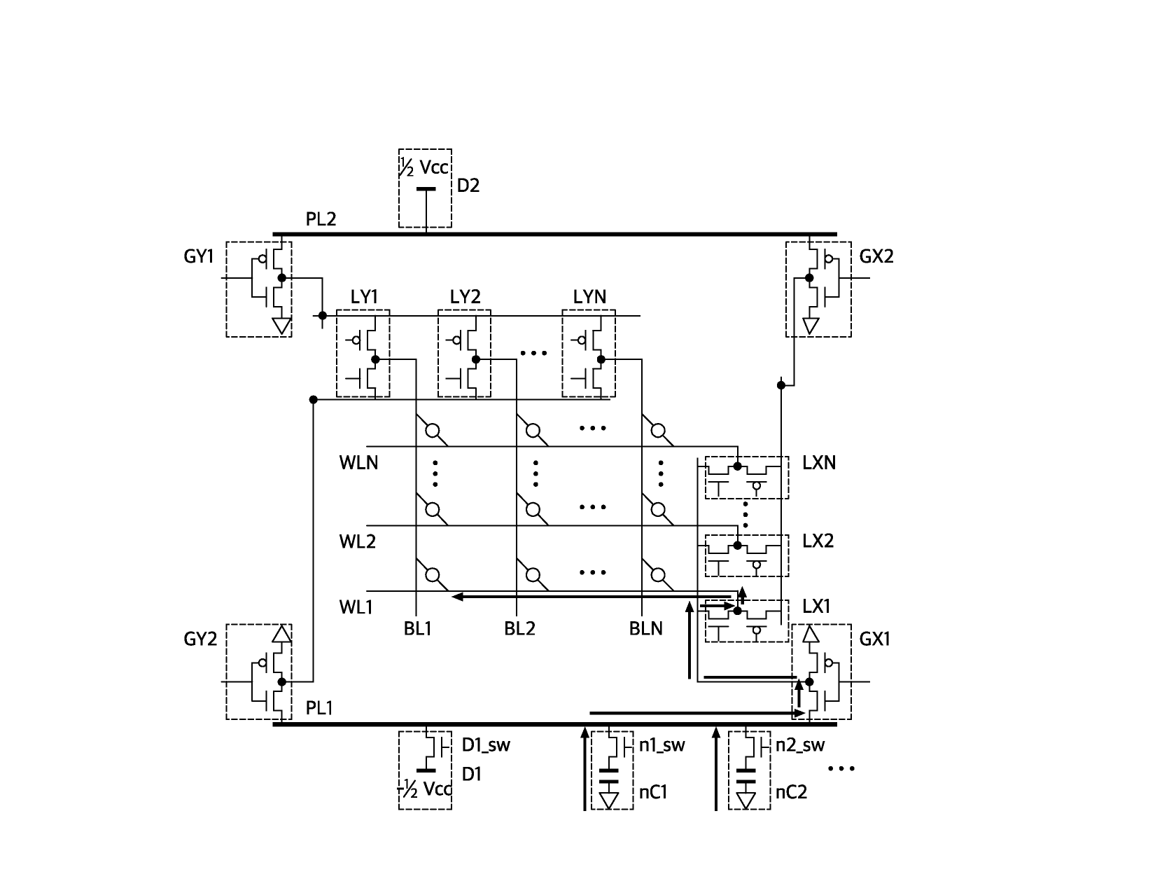

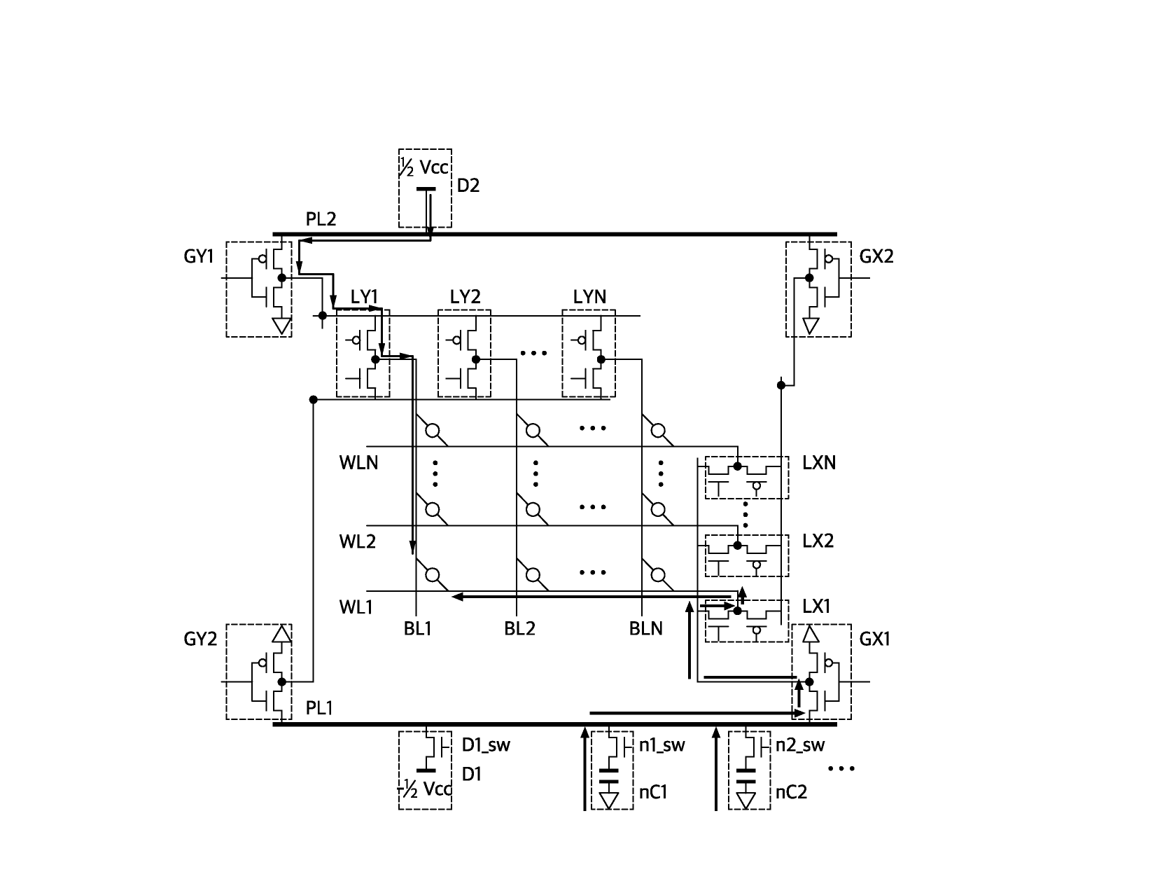

FIG. 6 is a waveform diagram for explaining a first program operation of a memory device according to an example embodiment. FIG. 7A to FIG. 7C are drawings for explaining step-by-step a first program operation according to the example embodiment.

Referring to FIG. 6, FIG. 7A to FIG. 7C, the memory device 100 according to an example embodiment may perform a first program operation. The first program operation may include applying a negative voltage (or pre-charging) first to a word line WL selected to store write data, and sequentially applying positive voltage (or pre-charging) to a selected bit line BL.

For example, the waveform in FIG. 6 may represent a signal applied to the gate of the NMOS included in a row local decoder LX, a signal applied to the gate of the PMOS included in the column local decoder LY, a control signal of the first driving switch D1_sw of the first driver circuit D1, a control signal of a switch nx_sw of the compensation circuit 130, the voltage V of the selected word line WL and the selected bit line BL, and a current I of the memory cell. FIG. 7A to FIG. 7C are illustrated based on an example in which the first word line WL1 is selected according to the address, and the first bit line BL1 is selected. In this case, the row local decoder LX of FIG. 6 may be the first row local decoder LX1, and the column local decoder LY of FIG. 6 may be the first column local decoder LY1. However, these are only provided as examples, and embodiments are not limited thereto.

Here, the first driving switch D1_sw may include an NMOS, and the switch nx_sw may include an NMOS. The switch nx_sw may be connected between the capacitor and the first power line PL1. The switch nx_sw may be the switch of one capacitor circuit among the switches n1_sw and n2_sw of the capacitor circuits nC1 and nC2. In an example embodiment, the NMOS may be turned on based on the input signal being in a high state, and the NMOS may be turned off based on the input signal being in a low state. The PMOS may be turned off based on the input signal is in a high state and turned on based on the input signal being in a low state. Below, an example of the control circuit 150 is described in which the first global decoder pair (e.g., the first row global decoder GX1 and the first column global decoder GY1) is selected depending on or based on a value of write data.

Referring to FIG. 6 and FIG. 7A, the memory device 100 may start a first program operation at a first timepoint t1.

At the first timepoint t1, the first driving switch D1_sw of the first driver circuit D1 may be turned on. In an example embodiment, the first driving switch D1_sw may remain turned-on until a second timepoint t2. While the first driving switch D1_sw is turned on, the first driver circuit D1 may output the first driving voltage (-1/2Vcc) to the first power line PL1. In an example embodiment, the first row global decoder GX1 may be turned on at the first timepoint t1, and may maintain the turned-on state until a fifth timepoint t5. While the first row global decoder GX1 is turned on, the first power line PL1 and a plurality of row local decoders (e.g., the first row local decoder LX1 to the Nth row local decoder LXN) may be connected.

At the first timepoint t1, the NMOS included in the row local decoder LX may be turned on, and the NMOS may maintain the turned-on state until the fifth timepoint t5. The row local decoder LX may be connected to the selected word line WL. While the first row global decoder GX1 and the row local decoder LX are turned on, the first power line PL1 and the optional word line WL may be connected. The voltage based on the first driving voltage (-1/2Vcc) of the first power line PL1 may be applied to the selected word line WL through the first row global decoder GX1 and the row local decoder LX. For example, the charge may be provided to the selected word line WL by the first driving voltage (-1/2Vcc) of the first power line PL1. The voltage based on the first driving voltage (-1/2Vcc) may have the same polarity (for example, negative) as the first driving voltage (-1/2Vcc), and may be the voltage at which a voltage drop occurs from the first driving voltage (-1/2Vcc). From the first timepoint t1 to the second timepoint t2, the voltage of the selected word line WL gradually increases to reach the first reference value (ref1).

Referring to FIG. 6 and FIG. 7B, at the second timepoint t2, the first driving switch D1_sw of the first driver circuit D1 may be turned off. While the first driving switch D1_sw is turned off, the output of the first driving voltage (-1/2Vcc) from the first driver circuit D1 may be blocked. In this case, the first power line PL1 may be floated. While the first power line PL1 is floating, the voltage of the selected word line WL may be gradually increased. This may be due to leakage current.

Referring to FIG. 6 and FIG. 7C, the first column global decoder GY1 may be turned on at a third timepoint t3, and maintained in the turned-on state until the fifth timepoint t5. While the first column global decoder GY1 is turned on, the second power line PL2 may be connected to a plurality of column local decoders (e.g., the first column local decoder LY1 to the Nth column local decoder LYN).

At the third timepoint t3, the PMOS included in the column local decoder LY may be turned on, and maintained in the turned-on state until the fifth timepoint t5. The column local decoder LY may be connected to the selected bit line BL. While the first column global decoder GY1 and the column local decoder LY are turned on, the second power line PL2 and the optional bit line BL may be connected. The voltage based on the second driving voltage (1/2Vcc) of the second power line PL2 may be applied to the selected bit line BL through the first column global decoder GY1 and the column local decoder LY. For example, charge may be provided to the selected bit line BL by the second driving voltage (1/2Vcc) of the second power line PL2. The voltage based on the second driving voltage (1/2Vcc) may have the same polarity (for example, positive) as the second driving voltage (1/2Vcc), and may be the voltage at which a voltage drop occurs from the second driving voltage (1/2Vcc). From the third timepoint t3 to the fifth timepoint t5, the voltage of the selected bit line BL may gradually increase until saturation.

In an example embodiment, each of the first column global decoder GY1 and the column local decoder LY may be turned on at a time earlier than the third timepoint t3. For example, each of the first column global decoder GY1 and the column local decoder LY may be turned on at the second timepoint t2. In an example embodiment, the first column global decoder GY1 and the column local decoder LY may both be turned on after the first timepoint t1.

After the third timepoint t3, the voltage difference between the selected bit line BL and the selected word line WL may gradually increase, and the voltage difference may reach the threshold value Vth at a fourth timepoint t4. The threshold value Vth may indicate the voltage difference at which the resistance of the memory cell drops sharply. Here, the charge accumulated in the selected word line WL and the selected bit line BL may be discharged, causing the current I to increase momentarily. In this case, the current may occur for a very short time, resulting in only low power consumption, and the program operation may be performed normally. For example, according to example embodiments, by separating the timing of applying voltage to the selected word line WL and the selected bit line BL without a separate current source, program operation may be performed while reducing power consumption.

At the fifth timepoint t5, the memory device 100 may terminate the first program operation. For example, at the fifth timepoint t5, the NMOS included in the row local decoder LX, the PMOS included in the column local decoder LY, the first driving switch D1_sw, and the switch nx_sw of the compensation circuit 130 may be turned off.

According to embodiments, the amount of charge lost due to leakage current may vary depending on or based on the area of the memory cell on the selected word line WL. For example, in a near area in which the distance to the word line contact is relatively small, a relatively small amount of charge may be lost. However, in a far area in which the distance to the word line contact is relatively large, a relatively large amount of charge may be lost. After the first power line PL1 is floated, when the charge of the selected word line WL is lost, there may be cases in which the voltage difference between the selected bit line BL and the selected word line WL does not reach the threshold value Vth. Embodiments of the present disclosure may provide a memory device 100 that performs program operations normally by compensating for the charge based on the degree of charge loss depending on the area.

In an example embodiment, at the first timepoint t1, the switch nx_sw may be turned on. In this case, the capacitor of the capacitor circuit including the switch nx_sw may be connected to the first power line PL1. With respect to the capacitor, while the first driving voltage (-1/2Vcc) is output to the connected first power line PL1, the negative charge may be applied by the first driving voltage (-1/2Vcc). In an example embodiment, the switch nx_sw may remain the turned-on state until the second timepoint t2 or the fifth timepoint t5.

In an example embodiment, the control circuit 150 may identify an area including a memory cell in the cell array 110 based on an address. The area of the cell array 110 may include a first area and a second area. The second area may be an area further away from the contacts connected to the decoder circuit 140 than the first area is from the contacts. For example, contact may include the word line contact.

As an example, based on the area of the memory cell being identified as the second area, the switch nx_sw may maintain the turned-on state from the second timepoint t2 to the fifth timepoint t5. The capacitor of the capacitor circuit including the switch nx_sw may be connected to the first power line PL1. The capacitor may discharge the charge to the first power line PL1, thereby controlling the charge of the selected word line WL. For example, the charge released from the capacitor may be provided to the selected word line WL through the first row global decoder GX1 and the row local decoder LX from the first power line PL1 connected to the capacitor. For example, the charge of the selected word line WL of the memory cell included in the second area may be compensated using a capacitor circuit connected to the floating first power line PL1.

As another example, based on the area of the memory cell being identified as the first area, the switch nx_sw is turned off at the second timepoint t2, and maintain the turn-off state until the fifth timepoint t5. In this case, the charge of the selected word line WL connected to the memory cell included in the first area may not be compensated. In some embodiments, the charge may be compensated with a smaller compensation amount for memory cells included in the first area compared to the second area. For example, based on the area of the memory cell being identified as the first area, the switch nx_sw may maintain the turn-off state from the first timepoint t1 to the fifth timepoint t5.

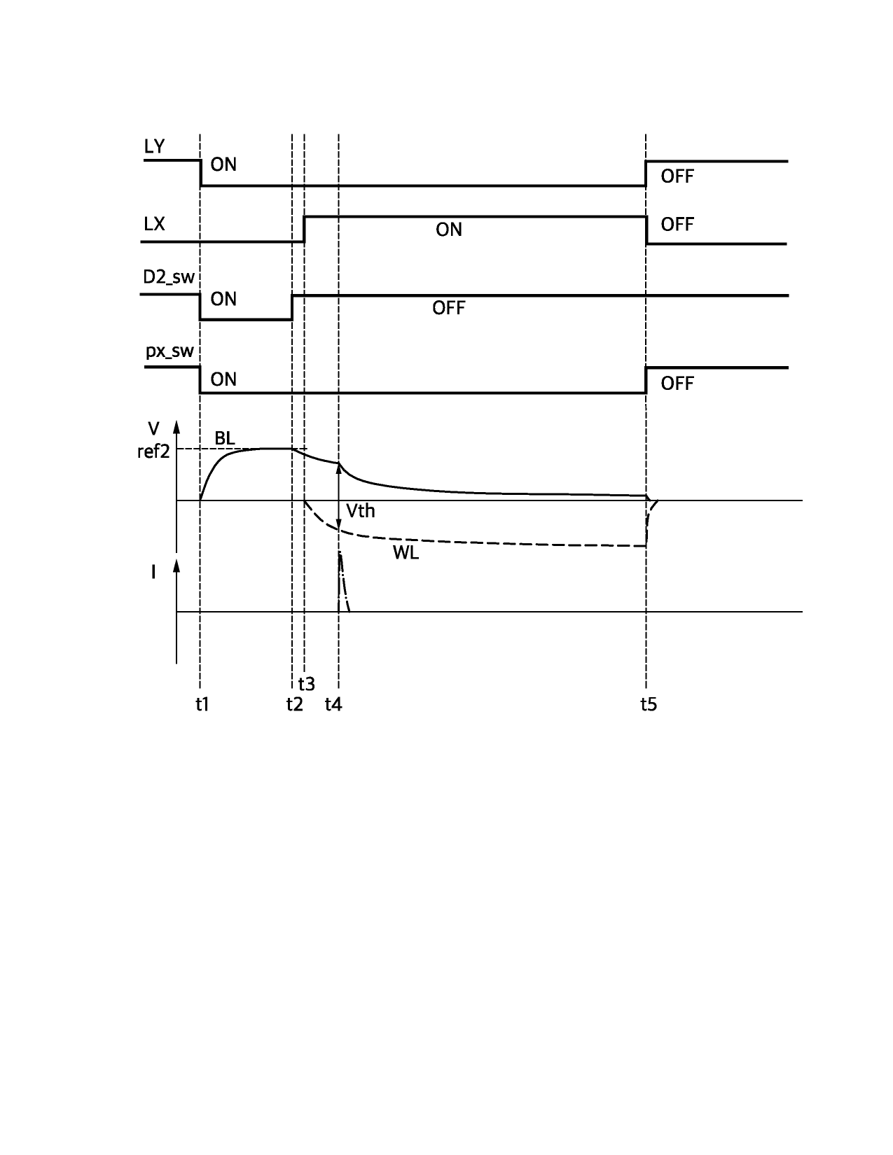

FIG. 8 is a waveform diagram for explaining a second program operation of a memory device according to an example embodiment.

FIG. 8 illustrates waveforms for the second program operation of the memory device 100 according to example embodiment. The second program operation may include applying a positive voltage (or pre-charging) first to the selected bit line BL to store write data, and sequentially applying negative voltage (or pre-charging) to the selected word line WL.

For example, the waveforms of FIG. 8 may represent a signal applied to the gate of the PMOS included in the column local decoder LY, a signal applied to the gate of the NMOS included in the row local decoder LX, a control signal of the second driving switch D2_sw of the second driver circuit D2, a control signal of a switch px_sw in the compensation circuit 130, the voltage V of the selected word line WL and the selected bit line BL, and the current I of the memory cell.

Here, the second driving switch D2_sw may include a PMOS, and the switch px_sw may include a PMOS. The switch px_sw may be connected between the capacitor and the second power line PL2. The switch px_sw may be the switch of one capacitor circuit among the switches p1_sw and p2_sw of the capacitor circuits pC1 and pC2. In an example embodiment, the NMOS may be turned on based on the input signal being in a high state and turned off based on the input signal being in a low state. The PMOS may be turned off based on the input signal being in a high state and turned on based on the input signal being in a low state. Below, an example of the control circuit 150 is described in which the first global decoder pair (the first row global decoder GX1 and the first column global decoder GY1) is selected depending on or based on the value of write data.

Referring to FIG. 8, the memory device 100 may start a second program operation at the first timepoint t1.

At the first timepoint t1, the second driving switch D2_sw of the second driver circuit D2 may be turned on. In an example embodiment, the second driving switch D2_sw may be maintained in the turned-on state until the second timepoint t2. While the second driving switch D2_sw is turned on, the second driver circuit D2 may output the second driving voltage (1/2Vcc) to the second power line PL2. In an example embodiment, the first column global decoder GY1 may be turned on at the first timepoint t1, and may be maintained in the turned-on state until the fifth timepoint t5. While the first column global decoder GY1 is turned on, the first power line PL1 and plurality of column local decoders (e.g., the first column local decoder LY1 to the Nth column local decoder LYN) may be connected.

At the first timepoint t1, the PMOS included in the column local decoder LY may be turned on, and maintain the turned-on state until the fifth timepoint t5. The column local decoder LY may be connected to the selected bit line BL. While the first column global decoder GY1 and the column local decoder LY are turned on, the second power line PL2 and the optional bit line BL may be connected. The voltage based on the second driving voltage (1/2Vcc) of the second power line PL2 may be applied to the selected bit line BL through the first column global decoder GY1 and the column local decoder LY. For example, the charge may be provided to the selected bit line BL by the second driving voltage (1/2Vcc) of the second power line PL2. The voltage based on the second driving voltage (1/2Vcc) may have the same polarity (for example, positive) as the second driving voltage (1/2Vcc), and may be the voltage at which a voltage drop occurs from the second driving voltage (1/2Vcc). From the first timepoint t1 to the second timepoint t2, the voltage of the selected bit line BL may gradually increase to reach the second reference value (ref2).

At the second timepoint t2, the second driving switch D2_sw may be turned off. While the second driving switch D2_sw is turned off, the output of the second driving voltage (1/2Vcc) from the second driver circuit D2 may be blocked. In this case, the second power line PL2 may be floated. While the second power line PL2 is floating, the voltage of the selected bit line BL may gradually decrease. This may be due to leakage current.

At the third timepoint t3, the first row global decoder GX1 may be turned on, and may be maintained in the turned-on state until the fifth timepoint t5. While the first row global decoder GX1 is turned on, the first power line PL1 and plurality of row local decoders (the first row local decoder LX1 to the Nth row local decoder LXN) may be connected.

At the third timepoint t3, the NMOS included in the row local decoder LX may be turned on, and may be maintained in the turned-on state until the fifth timepoint t5. The row local decoder LX may be connected to the selected word line WL. While the first row global decoder GX1 and the row local decoder LX are turned on, the first power line PL1 and the selected word line WL may be connected. The voltage based on the first driving voltage (-1/2Vcc) of the first power line PL1 may be applied to the selected word line WL through the first row global decoder GX1 and the row local decoder LX. For example, charge may be provided to the selected word line WL by the first driving voltage (-1/2Vcc) of the first power line PL1. The voltage based on the first driving voltage (-1/2Vcc) may have the same polarity (for example, negative) as the first driving voltage (-1/2Vcc), and may be the voltage at which a voltage drop occurs from the first driving voltage (-1/2Vcc). From the third timepoint t3 to the fifth timepoint t5, the voltage of the selected word line WL may gradually decrease until saturation.

After the third timepoint t3, the voltage difference between the selected bit line BL and the selected word line WL gradually may increase, and the voltage difference may reach the threshold value Vth at the fourth timepoint t4. The threshold value Vth may indicate the voltage difference at which the resistance of the memory cell drops sharply. Here, the charge accumulated in the selected word line WL and the selected bit line BL may be discharged, causing the current I to increase momentarily, and the program operation may be performed normally.

At the fifth timepoint t5, the memory device 100 may terminate the first program operation. For example, at the fifth timepoint t5, the NMOS included in the row local decoder LX, the PMOS included in the column local decoder LY, the second driving switch D2_sw, and the switch px_sw may be turned off.

In an example embodiment, at the first timepoint t1, the switch px_sw may be turned on. In this case, the capacitor of the capacitor circuit including the switch px_sw may be connected to the second power line PL2. With respect to the capacitor, while the second driving voltage (1/2Vcc) is output to the second power line PL2, the positive charge may be charged by the second driving voltage (1/2Vcc). In an example embodiment, the switch px_sw may remain the turned-on state until the second timepoint t2 or the fifth timepoint t5.

In an example embodiment, the control circuit 150 may identify an area including a memory cell in the cell array 110 based on an address. The area of the cell array 110 may include a first area and a second area. The second area may be an area that is further away from the contact connected to the decoder circuit 140 than the first area is from the contact. For example, a contact may include a bit line contact.

As an example, based on the area of the memory cell being identified as the second area, the switch px_sw may be maintained in the turned-on state from the second timepoint t2 to the fifth timepoint t5. The capacitor of the capacitor circuit including the switch px_sw may be connected to the second power line PL2. The capacitor may discharge the charge to the second power line PL2 to control the charge of the selected bit line BL. For example, the charge released from the capacitor may be provided to the selected bit line BL through the first column global decoder GY1 and the column local decoder LY from the second power line PL2 connected to the capacitor. For example, the charge of the selected bit line BL of the memory cell included in the second area may be compensated by using a capacitor circuit connected to the floating second power line PL2.

As another example, based on the area of the memory cell being identified as the first area, the switch px_sw may be turned off at the second timepoint t2, and may be maintained in the turn-off state until the fifth timepoint t5. In this case, the charge of the selected bit line BL connected to the memory cell included in the first area may not be compensated. In some embodiments, the charge may be compensated for with a smaller compensation amount for memory cells included in the first area compared to the second area.

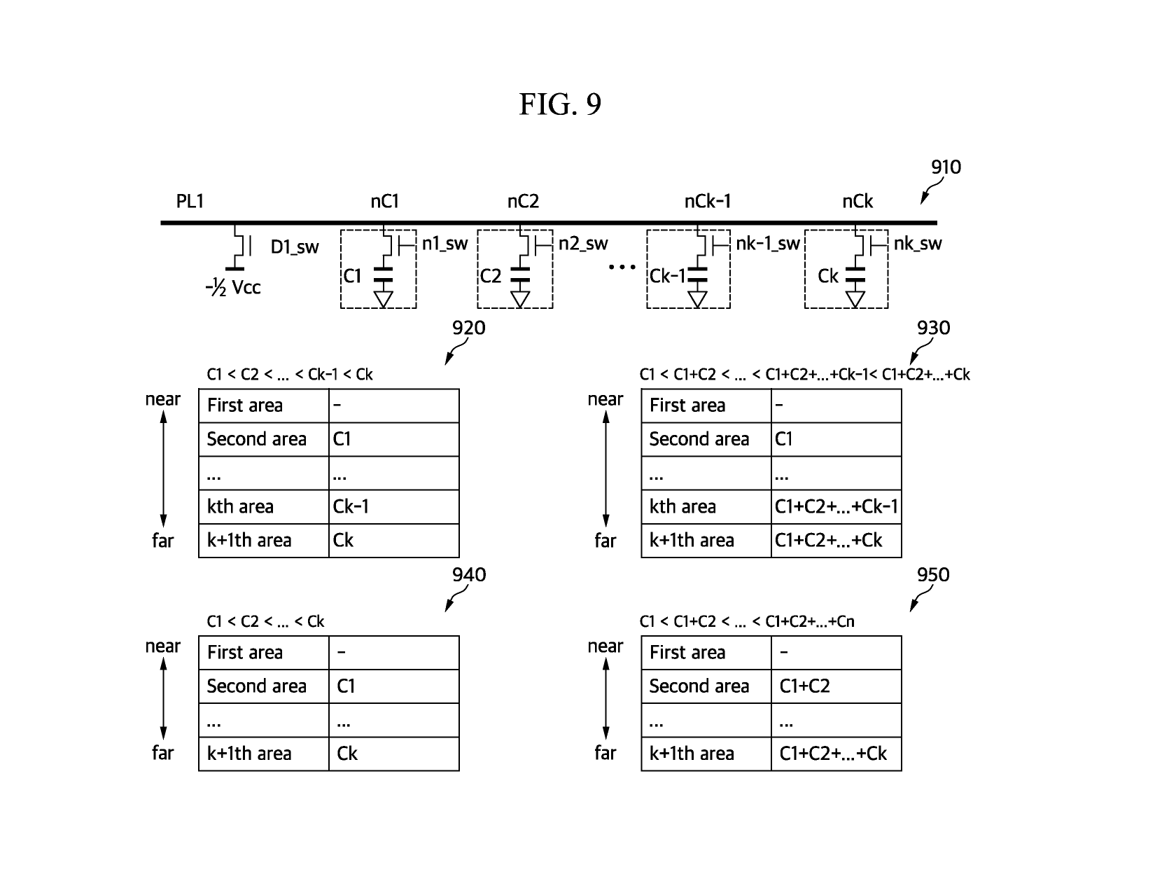

FIG. 9 is a drawing to explain the relationship between a compensation circuit and an address according to an example embodiment.

Referring to FIG. 9, in an example embodiment, the compensation circuit 130 may include a plurality of capacitor circuits 910. The plurality of capacitor circuits 910 may include the first capacitor circuit nC1 to a kth capacitor circuit nCk connected to the first power line PL1. Here, k may denote a natural number greater than or equal to 2 (or an integer greater than 1). The first capacitor circuit nC1 may include a first capacitor and the first switch n1_sw. The first switch n1_sw may be connected between the first power line PL1 and the first capacitor. Similarly, each of the second capacitor circuits nC2 to the kth capacitor circuit nCk may include respectively a corresponding capacitor and a corresponding switch. The first power line PL1 may be supplied with or blocked from the first driving voltage (-1/2Vcc) of the first polarity depending on or based on the switching of the first driving switch D1_sw.

In an example embodiment, the control circuit 150 may identify an area including a memory cell in the cell array 110 based on an address. For example, the control circuit 150 may identify an area including a memory cell in the cell array 110 based on the first word line WL1 and the first bit line BL1 being selected. Based on charge being supplied from the floating first power line PL1 through the first word line WL1, the control circuit 150 may identify the area of the first memory cell MC1 connected to the first word line WL1 and the first bit line BL1 according to the column address of the first bit line BL1. The control circuit 150 may adjust the charge provided to the memory cell by controlling the compensation circuit 130 based on the identified area.

In an example embodiment, a table in which capacitors (or switches of capacitor circuits) having specific capacitances are allocated to a plurality of areas may be created in advance and stored in the memory device 100. While the first power line PL1 is floating, the switch may be turned on so that a capacitor having the capacitance assigned to the area of the memory cell is connected to the first power line PL1.

For example, based on the capacitances (a first capacitance C1 to a kth capacitance Ck) of each of multiple capacitors being different, either a first table 920 or a third table 940 may be generated. In an example embodiment, a value of each capacitance may gradually increase from the first capacitance C1 to the kth capacitance Ck.

In an example embodiment, the first table 920 may include a first area to a k+1th area. The closer to the first area, an area may be closer to the contact, and the closer to the k+1th area, an area may be farther from the contact. Here, the first area is the area closest to the contact, and based on the memory cell being included in the first area, compensation may not be provided when the program is running. In this case, no capacitor may be allocated in the first area. In order to have a larger compensation amount as an area is closer to the k+1th area when the program runs, a capacitor with larger capacitance may be allocated.

In an example embodiment, the third table 940 may include first to kth areas. The closer to the first area, an area may be closer to the contact, and the closer to a kth area, an area may be farther from the contact. Here, the first area may be the area closest to the contact, and based on the memory cell being included in the first area, the first capacitor with the smallest first capacitance C1 may be allocated to compensate with the smallest compensation amount during the program operation. In order to have a larger compensation amount as an area is closer to the kth area when the program is running, a capacitor with larger capacitance may be allocated.

In an example embodiment, based on the capacitance of each of the plurality of capacitors (e.g., the first capacitance C1 to the kth capacitance Ck) being the same, either a second table 930 or a fourth table 950 may be created. Here, each of the first capacitance C1 to the kth capacitance Ck may have the same value.

In an example embodiment, the second table 930 may include the first area to the k+1th area. The closer to the first area, an area may be closer to the contact, and the closer to the k+1th area, an area may be farther from the contact. Here, the first area mau be the area closest to the contact, and based on the memory cell being included in the first area, compensation may not be provided when the program is running. In this case, a capacitor may not be allocated in the first area. In order to ensure that the sum of capacitances has a larger compensation amount as an area is closer to the k+1th area when the program is running, a greater number of capacitor may be allocated.

In an example embodiment, the fourth table 950 may include first to kth areas, closer to the first area, an area may be closer to the contact, and the closer to the k area, an area may be farther from the contact. Here, the first area may be the area closest to the contact, and in order for the smallest compensation amount to be used to compensate for program operation for a memory cell that is included in the first area, one first capacitance C1 may be allocated. In order for the sum of the capacitances to have a larger compensation amount as an area is closer to the k area when the program is running, a greater number of capacitors may be allocated. According to embodiments, the compensation circuit 130 may include a plurality of capacitor circuits connected to the second power line, and the above description applies similarly thereto.

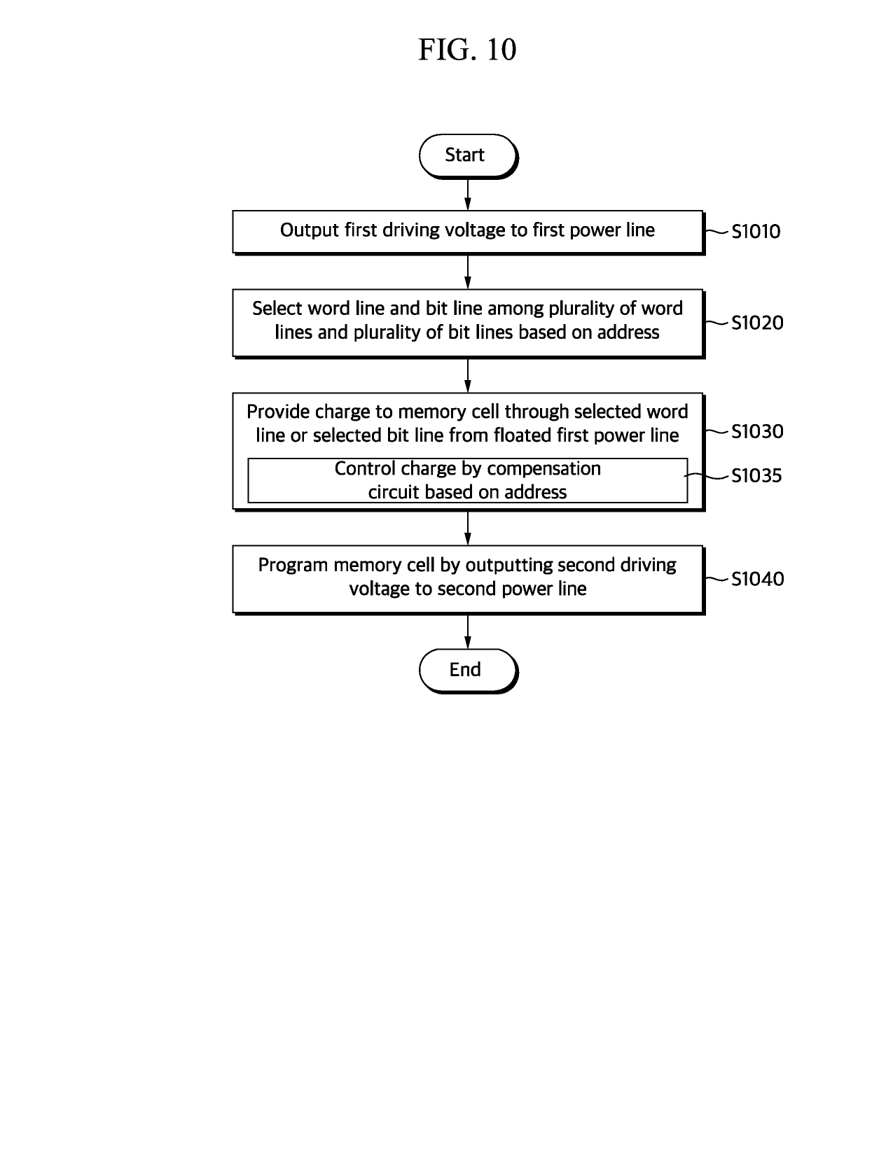

FIG. 10 is a flowchart illustrating an operation method of a memory device according to an example embodiment.

Referring to FIG. 10, a method of operating the memory device 100 may include operation S1010 that includes outputting a first driving voltage to a first power line, operation S1020 that includes selecting a word line and a bit line among a plurality of word lines and a plurality of bit lines based on an address by the decoder circuit 140, operation S1030 that includes providing charge to a memory cell through a selected word line or a selected bit line from a floating first power line, and operation S1040 that includes programming the memory cell by outputting the second driving voltage to the second power line. Operation S1030 that includes providing the charge may include operation S1035 that includes controlling charge by the compensation circuit 130 based on the address.

The memory device 100 may include the cell array 110 including a plurality of memory cells, the decoder circuit 140 and the compensation circuit 130. In an example embodiment, the decoder circuit 140 and the compensation circuit 130 may be connected to the first power line. The cell array 110 may include a plurality of memory cells. Each of the plurality of memory cells may be connected to one corresponding word line and one corresponding bit line. The decoder circuit 140 may be connected to a plurality of word lines and a plurality of bit lines. An address may include a row address indicating a word line and a column address indicating a bit line.

In an example embodiment, operation S1010 may include connecting the first capacitor of the compensation circuit 130 to the first power line. For example, based on the first switch included in the compensation circuit 130 being turned on, the first capacitor may be connected to the first power line. In this case, the first capacitor may be charged through the first power line.

In an example embodiment, operation S1035 may include controlling the amount of the charge.

In an example embodiment, operation S1035 may include identifying an area including a memory cell in the cell array 110 based on an address, and selectively connecting the first capacitor included in the compensation circuit 130 to the first power line based on the identified area. For example, depending on or based on the identified area, the first capacitor may be connected or blocked from the first power line.

In an example embodiment, the selectively connecting the first capacitor may include blocking the first capacitor from the first power line while the first power line is floating based on the identified area being the first area, and connecting the first capacitor to the first power line while the first power line is floating based on the identified area being the second area. The second area may be an area that is further from the reference point than the first area from the reference point. The reference point may be a word line contact or a bit line contact. In an example embodiment, the second area may be an area having a greater charge leakage than the first area.

In an example embodiment, the compensation circuit 130 may further include a second capacitor having a capacitance greater than a capacitance of the first capacitor.

In an example embodiment, the selectively connecting the capacitor may include, based on the identified area being the first area, connecting the first capacitor to the first power line and blocking the second capacitor from the first power line while the first power line is floating. The selectively connecting the first capacitor may include, based on the identified area being a second area, blocking the first capacitor from the first power line and connecting the second capacitor to the first power line while the first power line is floating. Here, the second area may be further away from the contact that connects the selected word line or the selected bit line to the decoder circuit 140 than the first area is from the contact.

In an example embodiment, the compensation circuit 130 may further include a second capacitor having a capacitance that is equal to a capacitance of the first capacitor.

In an example embodiment, the selectively connecting the first capacitor may include, based on the identified area being the first area, connecting one capacitor from among the first capacitor and the second capacitor to the first power line and blocking the remaining capacitor from the first power line while the first power line is floating. The selectively connecting the first capacitor may include, based on the identified area being the second area, connecting the first capacitor and the second capacitor to the first power line while the first power line is floating. The second area may be further away from the contact that connects the selected word line or the selected bit line to the decoder circuit 140 than the first area is from the contact.

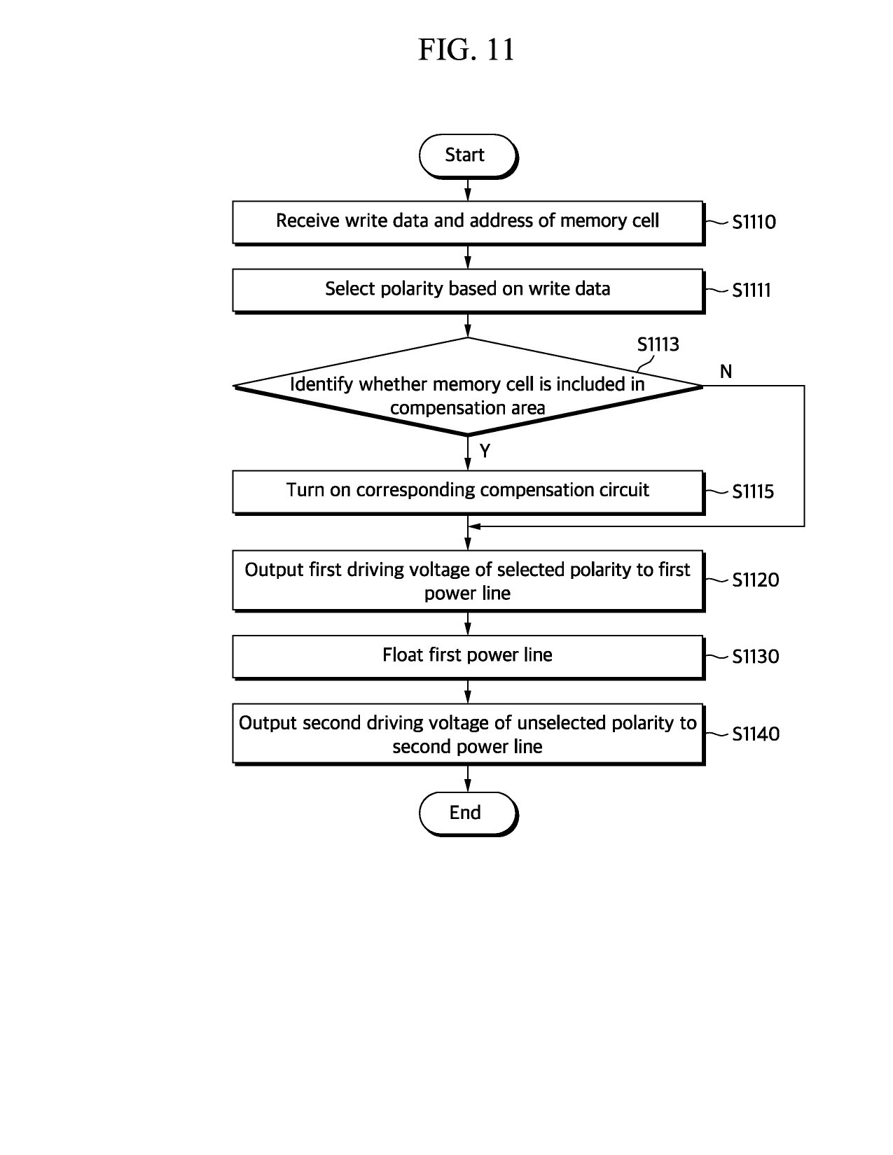

FIG. 11 is a flowchart for explaining an operation method of a memory device according to an example embodiment.

Referring to FIG. 11, the memory device 100 according to an example embodiment may receive write data and addresses of memory cells at operation S1110. For example, the write data and the addresses may be received from external devices. The address may include a row address corresponding to a word line and a column address corresponding to a bit line.

The memory device 100 may select polarity based on the write data at operation S1111. For example, based on a value of write data being a first value, the memory device 100 may select the first polarity (for example, negative or positive). Based on the value of write data being a second value, the memory device 100 may select the second polarity (for example, positive or negative). The memory device 100 may select a global decoder pair corresponding to the selected polarity. For example, based on the first global decoder pair being selected, a negative voltage may be applied to the selected word line, and a positive voltage may be applied to the selected bit line. For example, based on the second global decoder pair being selected, a positive voltage may be applied to the selected word line, and a negative voltage may be applied to the selected bit line.

The memory device 100 may identify whether a memory cell is included in a compensation area at operation S1113. In an example embodiment, the memory device 100 may identify the area of a memory cell and identify whether the area of the memory cell is the compensation area. For example, the memory device 100 may identify an area including a memory cell among a plurality of areas depending on or based on the address corresponding to the line to which the voltage is applied later between the selected word line and selected bit line. Here, the plurality of areas may be distinguished by the distance from the contact connected to the line to which the voltage is applied first between the selected word line and the selected bit line. A compensation area may refer to an area in which compensation for charge is required, and may be a predefined area depending on or based on the distance from the contact.

Based on the memory cell being included in the compensation area (Y at operation S1113), the memory device 100 may turn on the compensation circuit 130 corresponding to the compensation area at operation S1115. The compensation circuit 130 may include a capacitor for compensating for the charge provided to a line between the selected word line and the selected bit line to which voltage is applied first.

The memory device 100 may output the first driving voltage having the selected polarity (for example, negative or positive) to the first power line at operation S1120. In this case, a first voltage based on a first driving voltage of a first power line may be applied to a first line between the selected word line and the selected bit line. In an example embodiment, the compensation circuit 130 may be charged through the first power line.

The memory device 100 may float the first power line at operation S1130. In this case, the supply of first driving voltage may be cut off. The charge discharged in the compensation circuit 130 may be supplied to the first line through the first power line.

The memory device 100 may output a second driving voltage having the unselected polarity (for example, positive or negative) to the second power line at operation S1140. In this case, a second voltage based on the second driving voltage of the second power line may be applied to the second line between the selected word line and the selected bit line. When the voltage difference between the second line and the first line reaches the threshold value, data may be stored in memory cells.

According to embodiments, based on the memory cell being not included in the compensation area (N at operation S1113), the memory device 100 may turn off the compensation circuit 130.

The memory device 100 may output the first driving voltage of the selected polarity to the first power line at operation S1120. In this case, the first voltage based on the first driving voltage may be applied to the first line between the selected word line and the selected bit line. The memory device 100 may float the first power line at operation S1130. In this case, the supply of first driving voltage may be cut off. The second driving voltage having the polarity (for example, positive or negative) may be output to the second power line at operation S1140. In this case, the second voltage based on the second driving voltage of the second power line may be applied to the second line between the selected word line and the selected bit line. When the voltage difference between the second line and the first line reaches the threshold value, data may be stored in memory cells.

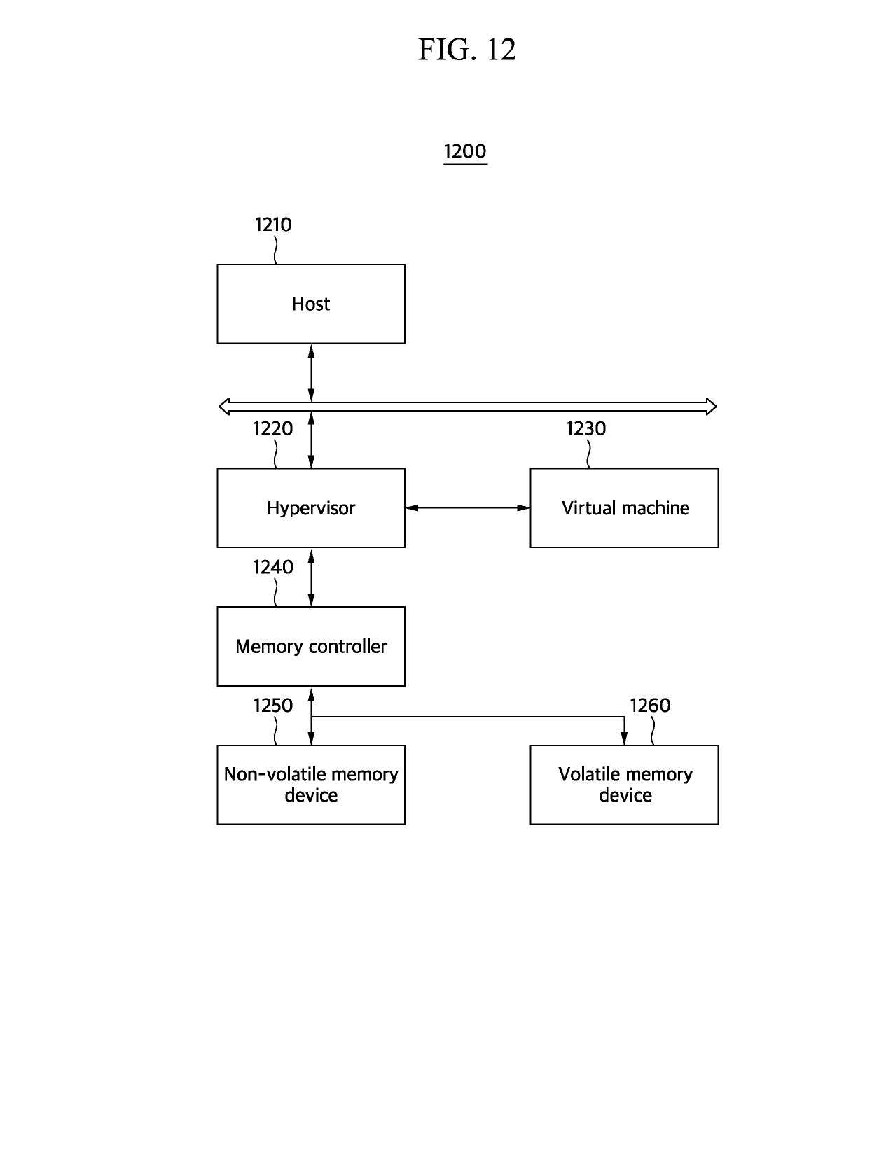

FIG. 12 is a drawing for explaining a storage device according to an example embodiment.

Referring to FIG. 12, in an example embodiment, a storage device 1200 may include a memory controller 1240 and a non-volatile memory device 1250. In an example embodiment, the storage device 1200 may further include at least one of a volatile memory device 1260, a hypervisor 1220, a virtual machine 1230 and a host 1210.

The host 1210 may include various processes such as a central processing unit, an application processing unit and so on. The host 1210 may directly access either the non-volatile memory device 1250 or the volatile memory device 1260 through the memory controller 1240, or exchange data. The host 1210 controls and monitors the overall operation of the system, and instruct the hypervisor 1220 to create, manage, terminate and so on the virtual machines 1230, if necessary.

The hypervisor 1220 may manage one or more virtual machines 1230 in a virtualization environment. The hypervisor 1220 may communicate with the virtual machine 1230 to manage and allocate system resources. For example, the hypervisor 1220 may dynamically allocate or adjust memory resources through the memory controller 1240 in order for each virtual machine 1230 to use memory efficiently.

The virtual machine 1230 may be a virtualized computing environment created and managed by the hypervisor 1220, and may run independent operating systems and applications. The virtual machine 1230 uses memory space allocated through the hypervisor, and access the memory controller 1240 to read or write data when needed. A single virtual machine 1230 may be treated as a completely independent environment logically while sharing physical resources with other virtual machines. This may allow system resources to be utilized efficiently, and help create a stable and secure computing environment.

The memory controller 1240 may process memory access requests transmitted from external devices, and control read/write operations for the non-volatile memory device 1250 and the volatile memory device 1260. The memory controller 1240 may communicate with external devices using the CXL protocol. The CXL protocol may enable high-speed data communication by providing low latency and high bandwidth. The external device may be the host 1210 or the hypervisor 1220. In an example embodiment, the memory controller 1240 may perform hierarchical data management between memory devices, data priority setting, error detecting and correcting (error correction code ECC) functions and so on to increase the data reliability and improve the overall performance and stability of the system. According to embodiments, the CXL protocol is only an example embodiment and may be implemented by modifying various protocols such as peripheral component interconnect express (PCIe) and non-volatile memory express (NVMe).

The non-volatile memory device 1250 may retain stored data even when power is cut off. The non-volatile memory device 1250 may perform read/write operations of data under the control of the memory controller 1240. The non-volatile memory device 1250 may include the memory device 100 described above. For example, the non-volatile memory device 1250 may include the cell array 110, the driver circuit 120, the compensation circuit 130, the decoder circuit 140, and the control circuit 150.

The cell array 110 may include a plurality of memory cells. The driver circuit 120 may apply the first driving voltage to the first power line and the second driving voltage to the second power line. The compensation circuit 130 may be connected to the first power line. The decoder circuit 140 may program the memory cells by selecting word lines and bit lines based on the address, and by providing charge through a selected word line or a selected bit line from the floating first power line. The control circuit 150 may control the compensation circuit 130 to adjust charge based on address. The above description may be equally applied to each component.

The volatile memory device 1260 may retain data only while power is supplied. The volatile memory device 1260 may serve as temporary storage for the system, and may be used primarily in cases in which high-speed data access is required. In an example embodiment, the volatile memory device 1260 may provide faster read/write speeds than the non-volatile memory device 1250. In an example embodiment, depending on or based on how frequently the data is accessed, data with a higher access frequency than the reference value may be stored in the volatile memory device 1260, and data with a lower access frequency than the reference value may be stored in the non-volatile memory device 1250.

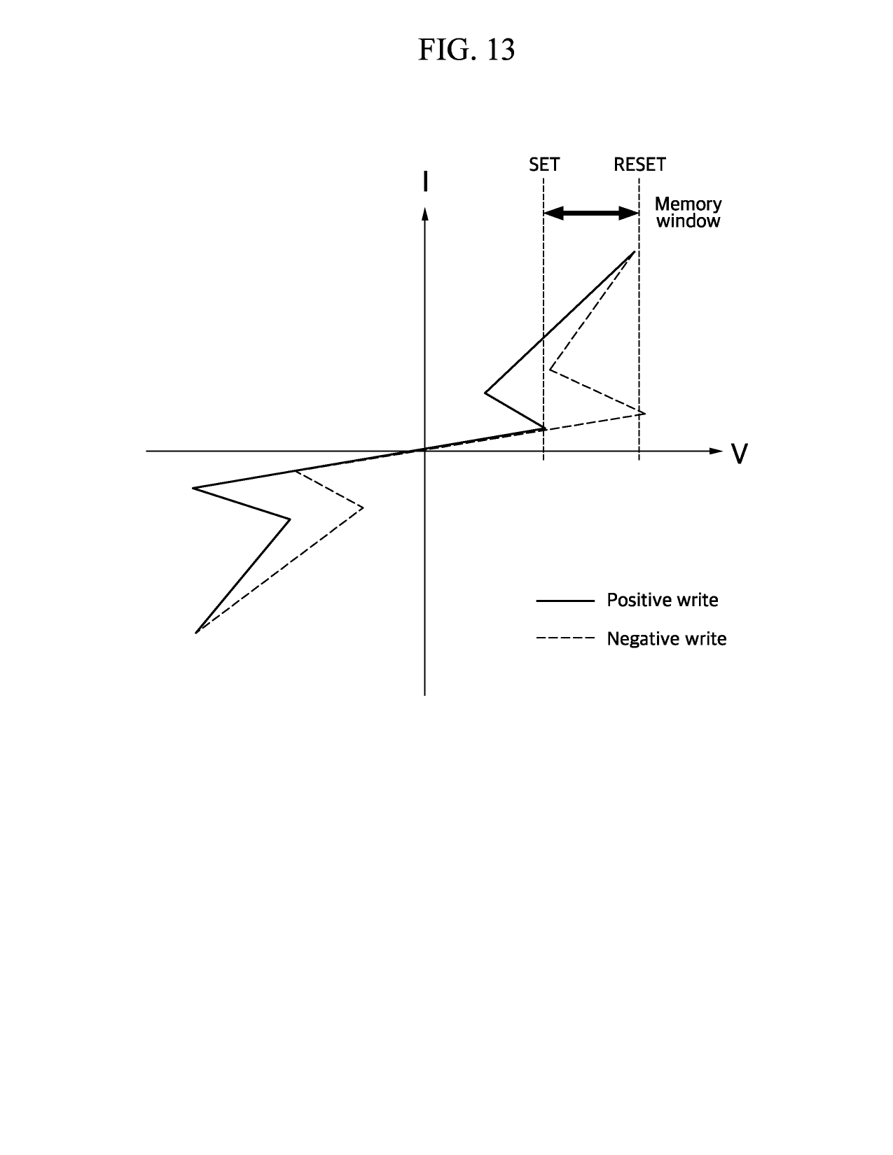

FIG. 13 is a drawing to explain characteristics of a memory cell according to an example embodiment.

Referring to FIG. 13, a memory cell according to an example embodiment may include a SOM device. The SOM device may have characteristics that at a certain threshold voltage or below the certain threshold voltage, a high resistance state is maintained, and when the threshold voltage is exceeded, the SOM device may perform both memory and selection functions.

The SOM device may have bidirectional switching characteristics that may switch between low resistance state and high resistance state depending on or based on the polarity of the voltage. For example, the threshold voltage of SOM device may change depending on or based on the polarity of the voltage. As illustrated in FIG. 13, a memory window may be formed between the “SET” state and the “RESET” state. For example, for positive writing, when the voltage applied to the SOM device gradually increases and is in a range higher than “SET,” the SOM device may have a low resistance state. As another example, in the case of negative writing, when the voltage applied to the SOM device gradually increases and does not reach a level higher than “RESET,” the SOM device may have a high resistance state. The SOM device may perform stable and low-power based program operations in a very short time. The memory device 100 according to an example embodiment of the present disclosure may achieve an effect of reducing power consumption of a program operation by controlling the timing at which voltage is applied to the word line and bit line of the memory cell using SOM device differently.

Example embodiments are described above with respect to the drawings in the present disclosure. In the present disclosure, the example embodiments are described using specific terms, but the terms are used solely for the purpose of explaining the technical ideas of the present disclosure and are not intended to limit the meaning or scope of the present disclosure as set forth in the claims. Therefore, those skilled in the art will understand that various modifications and equivalent example embodiments are possible without departing from the scope of thedisclosure.

What is claimed is:

1. A memory device comprising:
a cell array comprising a plurality of memory cells, wherein each memory cell from among the plurality of memory cells is connected to a corresponding word line from among a plurality of word lines and a corresponding bit line from among of a plurality of bit lines;
a driver circuit configured to output a first driving voltage to a first power line;
a compensation circuit connected to the first power line;
a decoder circuit configured to program a memory cell by selecting a word line and a bit line based on an address, and providing a charge from the first power line, wherein the charge is floated through the selected word line or the selected bit line; and
a control circuit configured to control the compensation circuit to adjust an amount of the charge based on the address.

2. The memory device of claim 1, wherein the compensation circuit comprises:
a first capacitor; and
a first switch between the first power line and the first capacitor.

3. The memory device of claim 2, wherein the control circuit is further configured to:
identify an area including the memory cell in the cell array based on the address; and
control the first switch based on the identified area.

4. The memory device of claim 3, wherein the control circuit is further configured to:
based on the identified area being a first area, deactivating the first switch while the first power line is floated; and
based on the identified area being a second area, activating the first switch while the first power line is floated,
wherein the selected word line or the selected bit line is connected to the decoder circuit by a contact,
wherein a distance between the contact and the second area is greater than a distance between the contact and the first area.

5. The memory device of claim 2, wherein the control circuit is further configured to activate the first switch while the driver circuit outputs the first driving voltage to the first power line.

6. The memory device of claim 2, wherein the compensation circuit further comprises:
a second capacitor; and
a second switch between the first power line and the second capacitor.

7. The memory device of claim 6, wherein the control circuit is further configured to:
identify an area including the memory cell in the cell array based on the address; and
control the first switch and the second switch based on the identified area.

8. The memory device of claim 7, wherein a capacitance of the first capacitor is less than a capacitance of the second capacitor.

9. The memory device of claim 8, wherein the control circuit is further configured to:
based on the identified area being a first area, activate the first switch, and deactivate the second switch, while the first power line is floated; and
based on the identified area being a second area, deactivate the first switch, and activate the second switch, while the first power line is floated,
wherein the selected word line or the selected bit line is connected to the decoder circuit by a contact, and
wherein a distance between the contact and the second area is greater than a distance between the contact and the first area.

10. The memory device of claim 7, wherein a capacitance of the first capacitor is equal to a capacitance of the second capacitor.

11. The memory device of claim 10, wherein the control circuit is further configured to:
based on the identified area being a first area, activate one switch from among the first switch and the second switch and turn off a remaining switch from among the first switch and the second switch, while the first power line is floated; and
based on the identified area being a second area, activate the first switch and the second switch, while the first power line is floated,
wherein the selected word line or the selected bit line is connected to the decoder circuit by a contact, and
wherein a distance between the contact and the second area is greater than a distance between the contact and the first area.

12. A method for operating a memory device including a cell array including a plurality of memory cells, a decoder circuit and a compensation circuit, the method comprising:
outputting a first driving voltage to a first power line;
using the decoder circuit, selecting a word line from among a plurality of word lines and a bit line from among a plurality of bit lines based on an address;
providing a charge to a memory cell from the first power line, wherein the charge is floated through the selected word line or the selected bit line; and
programming the memory cell by outputting a second driving voltage to a second power line,
wherein the providing of the charge comprises adjusting an amount of the charge using the compensation circuit based on the address.

13. The method of claim 12, wherein the adjusting of the charge comprises:
identifying an area including the memory cell included in the cell array based on the address; and
based on the identified area, connecting a first capacitor included in the compensation circuit to the first power line.

14. The method of claim 13, wherein connecting of the first capacitor comprises:
based on the identified area being a first area, blocking the first capacitor from the first power line while the first power line is floated; and
based on the identified area being a second area, connecting the first capacitor to the first power line while the first power line is floated.

15. The method of claim 13, wherein the outputting of the first driving voltage comprises connecting the first capacitor to the first power line.

16. The method of claim 13, wherein the compensation circuit comprises a second capacitor, and
wherein a capacitance of the second capacitor is greater than a capacitance of the first capacitor.

17. The method of claim 16, wherein the connecting of the first capacitor comprises:
based on the identified area being a first area, connecting the first capacitor to the first power line, and blocking the second capacitor from the first power line, while the first power line is floated; and
based on the identified area being a second area, blocking the first capacitor from the first power line, and connecting the second capacitor to the first power line, while the first power line is floated,
wherein the selected word line or the selected bit line is connected to the decoder circuit by a contact,
wherein a distance between the contact and the second area is greater than a distance between the contact and the first area.

18. The method of claim 13, wherein the compensation circuit comprises a second capacitor, and
wherein a capacitance of the second capacitor is equal to a capacitance of the first capacitor.

19. The method of claim 18, wherein the connecting of the first capacitor comprises:
based on the identified area being a first area, connecting one capacitor from among the first capacitor and the second capacitor to the first power line, and blocking a remaining capacitor from among the first capacitor and the second capacitor from the first power line, while the first power line is floated; and
based on the identified area being a second area, connecting the first capacitor and the second capacitor to the first power line, while the first power line is floated, and
wherein the selected word line or the selected bit line is connected to the decoder circuit by a contact, and
wherein a distance between the contact and the second area is greater than a distance between the contact and the first area.

20. A storage device comprising:
a memory controller configured to communicate with a host using a compute express link (CXL) protocol; and
a memory device comprising a decoder circuit, a compensation circuit, and a cell array comprising a plurality of memory cells,
wherein the memory device is configured to:
output a first driving voltage to a first power line;
using the decoder circuit, select a word line from among a plurality of word lines and a bit line from among a plurality of bit lines based on an address;
provide a charge to a memory cell from the first power line, wherein the charge is floated through the selected word line or the selected bit line;
program the memory cell by outputting a second driving voltage to a second power line; and
adjust an amount of the charge using the compensation circuit based on the address.
